(19) United States
(12) Patent Application Publication
(10) Pub. No.: US 2023/0420630 A1
(43) Pub. Date: Dec. 28, 2023

(54) IMAGE DISPLAY DEVICE AND METHOD FOR MANUFACTURING IMAGE DISPLAY DEVICE

(71) Applicant: NICHIA CORPORATION, Anan-shi (JP)

(72) Inventor: Hajime AKIMOTO, Anan-shi (JP)

(73) Assignee: NICHIA CORPORATION, Anan-shi (JP)

(21) Appl. No.: 18/462,540

(22) Filed: Sep. 7, 2023

Related U.S. Application Data
(63) Continuation of application No. PCT/JP2022/010022, filed on Mar. 8, 2022.

(30) Foreign Application Priority Data
Mar. 17, 2021 (JP) 2021-043514

(51) Int. Cl. H01L 33/62; H01L 25/075; H01L 33/32; H01L 25/16; H01L 27/12; H01L 33/00

(52) U.S. Cl. CPC H01L 33/62; H01L 25/0753; H01L 33/32; H01L 25/167; H01L 27/124; H01L 33/007; H01L 2933/0066

(57) ABSTRACT

A method for manufacturing an image display device includes: preparing a substrate, the substrate including a circuit and a first insulating film covering the circuit; forming a graphene-including layer on the first insulating film; forming a semiconductor layer on the graphene-including layer; forming a light-emitting element by etching the semiconductor layer, the light-emitting element including a bottom surface on the graphene-including layer, and a light-emitting surface at a side opposite to the bottom surface; forming a second insulating film covering the graphene-including layer, the light-emitting element, and the first insulating film; forming a first via extending through the first and second insulating films; and forming a wiring layer on the second insulating film. The first via is located between the wiring layer and the circuit and electrically connects the wiring layer and the circuit. The light-emitting element is electrically connected to the circuit via the wiring layer.

### CROSS-REFERENCE TO RELATED APPLICATIONS

The present application is a bypass continuation of PCT Application No. PCT/JP2022/010022, filed Mar. 8, 2022, which claims priority to Japanese Application No. 2021-043514, filed Mar. 17, 2021. The contents of these applications are hereby incorporated by reference in their entireties.

### BACKGROUND

Embodiments of the invention relate to a method for manufacturing an image display device and an image display device.

It is desirable to realize an image display device that is thin and has high luminance, a wide viewing angle, high contrast, and low power consumption. To satisfy such market needs, a display device that utilizes a self-luminous element is being developed.

There are expectations for the advent of a display device that uses a micro LED that is a fine light-emitting element as a self-luminous element. A method has been introduced as a method for manufacturing a display device that uses a micro LED in which individually-formed micro LEDs are sequentially transferred to a drive circuit. However, as the number of elements of micro LEDs increases with higher image quality such as full high definition, 4K, 8K, etc., if many micro LEDs are individually formed and sequentially transferred to a substrate in which a drive circuit and the like are formed, an enormous amount of time is necessary for the transfer process. Also, there is a risk that connection defects between the micro LEDs, the drive circuits, etc., may occur, and a reduction of the yield may occur.

In known technology, a semiconductor layer that includes a light-emitting layer is grown on a Si substrate; an electrode is formed at the semiconductor layer; subsequently, bonding is performed to a circuit board in which a drive circuit is formed (e.g., see Japanese Patent Publication No. 2002-141492).

### SUMMARY

According to certain embodiments of the present invention, a method for manufacturing an image display device is provided in which a transfer process of a light-emitting element is shortened, and yield is increased.

A method for manufacturing an image display device according to an embodiment of the invention includes a process of preparing a substrate that includes a circuit and a first insulating film covering the circuit, a process of forming a graphene-including layer on the first insulating film, a process of forming a semiconductor layer including a light-emitting layer on the graphene-including layer, a process of etching the semiconductor layer to form a light-emitting element that includes a bottom surface on the graphene-including layer and includes a light-emitting surface that is a surface at a side opposite to the bottom surface, a process of forming a second insulating film covering the graphene-including layer, the light-emitting element, and the first insulating film, a process of forming a first via extending through the first and second insulating films, and a process of forming a wiring layer on the second insulating film. The first via is located between the wiring layer and the circuit and electrically connects the wiring layer and the circuit. The light-emitting element is electrically connected to the circuit via the wiring layer.

An image display device according to an embodiment of the invention includes a circuit element, a first wiring layer electrically connected to the circuit element, a first insulating film covering the circuit element and the first wiring layer, a first part including the graphene located on the first insulating film, a light-emitting element that includes a bottom surface on the first part and includes a light-emitting surface that is a surface at a side opposite to the bottom surface, a second insulating film covering the first insulating film and a side surface of the light-emitting element, a second wiring layer located on the second insulating film, and a first via extending through the first and second insulating films. The first via is located between the first wiring layer and the second wiring layer and electrically connects the first wiring layer and the second wiring layer. The light-emitting element is electrically connected to the circuit element via at least one of the first wiring layer or the second wiring layer.

An image display device according to an embodiment of the invention includes multiple transistors, a first wiring layer electrically connected to the multiple transistors, a first insulating film covering the multiple transistors and the first wiring layer, a semiconductor layer that includes a third part including the graphene located on the first insulating film and includes multiple light-emitting surfaces at a surface at a side opposite to a surface on the third part, a second insulating film covering the first insulating film and a side surface of the semiconductor layer, a second wiring layer located on the second insulating film, and a via extending through the first and second insulating films. The via is located between the first wiring layer and the second wiring layer and electrically connects the first wiring layer and the second wiring layer. The semiconductor layer is electrically connected to the multiple transistors via the first and second wiring layers.

An image display device according to an embodiment of the invention includes multiple circuit elements, a first wiring layer electrically connected to the multiple circuit elements, a first insulating film covering the multiple circuit elements and the first wiring layer, multiple first parts including graphene located on the first insulating film, multiple light-emitting elements that include bottom surfaces on the multiple first parts and include light-emitting surfaces that are surfaces at sides opposite to the bottom surfaces, a second insulating film covering the first insulating film that side surfaces of the multiple light-emitting elements, a second wiring layer located on the second insulating film, and a first via extending through the first and second insulating films. The first via is located between the first wiring layer and the second wiring layer and electrically connects the first wiring layer and the second wiring layer. The multiple light-emitting elements are electrically connected respectively to the multiple circuit elements via at least one of the first wiring layer or the second wiring layer.

According to certain embodiments of the invention, a method for manufacturing an image display device is realized in which a transfer process of a light-emitting element is shortened, and the yield is increased.

According to certain embodiments of the invention, a high-definition image display device can be realized in which the light-emitting element is reduced in size.

### BRIEF DESCRIPTION OF THE DRAWINGS

FIG. 1 is a schematic cross-sectional view illustrating a portion of an image display device according to a first embodiment.

FIG. 2A is a cross-sectional view schematically showing a portion of an image display device according to a modification of the first embodiment.

FIG. 2B is a cross-sectional view schematically showing a portion of an image display device according to a modification of the first embodiment.

FIG. 2C is a cross-sectional view schematically showing a portion of an image display device according to a modification of the first embodiment.

FIG. 3 is a schematic block diagram illustrating the image display device of the first embodiment.

FIG. 4 is a schematic plan view illustrating a portion of the image display device of the first embodiment.

FIG. 5A is a schematic cross-sectional view illustrating a method for manufacturing the image display device of the first embodiment.

FIG. 5B is a schematic cross-sectional view illustrating the method for manufacturing the image display device of the first embodiment.

FIG. 6A is a schematic cross-sectional view illustrating the method for manufacturing the image display device of the first embodiment.

FIG. 6B is a schematic cross-sectional view illustrating the method for manufacturing the image display device of the first embodiment.

FIG. 7 is a schematic cross-sectional view illustrating the method for manufacturing the image display device of the first embodiment.

FIG. 8A is a schematic cross-sectional view illustrating a manufacturing method of a modification of the image display device of the first embodiment.

FIG. 8B is a schematic cross-sectional view illustrating the manufacturing method of the modification of the image display device of the first embodiment.

FIG. 9A is a schematic cross-sectional view illustrating a manufacturing method of a modification of the image display device of the first embodiment.

FIG. 9B is a schematic cross-sectional view illustrating the manufacturing method of the modification of the image display device of the first embodiment.

FIG. 10A is a schematic cross-sectional view illustrating the method for manufacturing the image display device of the first embodiment.

FIG. 10B is a schematic cross-sectional view illustrating the method for manufacturing the image display device of the first embodiment.

FIG. 10C is a schematic cross-sectional view illustrating the method for manufacturing the image display device of the first embodiment.

FIG. 10D is a schematic cross-sectional view illustrating the method for manufacturing the image display device of the first embodiment.

FIG. 11 is a schematic cross-sectional view illustrating a modification of the method for manufacturing the image display device of the first embodiment.

FIG. 12 is a schematic perspective view illustrating the image display device according to the first embodiment.

FIG. 13 is a schematic cross-sectional view illustrating a portion of an image display device according to a second embodiment.

FIG. 14 is a schematic block diagram illustrating the image display device of the second embodiment.

FIG. 15A is a schematic cross-sectional view illustrating a method for manufacturing the image display device of the second embodiment.

FIG. 15B is a schematic cross-sectional view illustrating the method for manufacturing the image display device of the second embodiment.

FIG. 16 is a schematic cross-sectional view illustrating the method for manufacturing the image display device of the second embodiment.

FIG. 17 is a schematic cross-sectional view illustrating a portion of an image display device according to a third embodiment.

FIG. 18A is a schematic cross-sectional view illustrating a method for manufacturing the image display device of the third embodiment.

FIG. 18B is a schematic cross-sectional view illustrating the method for manufacturing the image display device of the third embodiment.

FIG. 19A is a schematic cross-sectional view illustrating the method for manufacturing the image display device of the third embodiment.

FIG. 19B is a schematic cross-sectional view illustrating the method for manufacturing the image display device of the third embodiment.

FIG. 20A is a schematic cross-sectional view illustrating the method for manufacturing the image display device of the third embodiment.

FIG. 20B is a schematic cross-sectional view illustrating the method for manufacturing the image display device of the third embodiment.

FIG. 21 is a schematic cross-sectional view illustrating a portion of an image display device according to a fourth embodiment.

FIG. 22A is a schematic cross-sectional view illustrating a method for manufacturing the image display device of the fourth embodiment.

FIG. 22B is a schematic cross-sectional view illustrating the method for manufacturing the image display device of the fourth embodiment.

FIG. 23A is a schematic cross-sectional view illustrating the method for manufacturing the image display device of the fourth embodiment.

FIG. 23B is a schematic cross-sectional view illustrating the method for manufacturing the image display device of the fourth embodiment.

FIG. 24 is a schematic cross-sectional view illustrating a portion of an image display device according to a modification of the fourth embodiment.

FIG. 25A is a schematic cross-sectional view illustrating a method for manufacturing the image display device of the modification of the fourth embodiment.

FIG. 25B is a schematic cross-sectional view illustrating the method for manufacturing the image display device of the modification of the fourth embodiment.

FIG. 26 is a schematic cross-sectional view illustrating a portion of an image display device according to a fifth embodiment.

FIG. 27 is a schematic cross-sectional view illustrating a portion of an image display device according to a modification of the fifth embodiment.

FIG. 28 is a graph illustrating a characteristic of a pixel LED element.

FIG. 29 is a block diagram illustrating an image display device according to a sixth embodiment.

FIG. 30 is a block diagram illustrating an image display device according to a modification of the sixth embodiment.

### DETAILED DESCRIPTION

Embodiments of the invention will now be described with reference to the drawings.

The drawings are schematic or conceptual, and the relationships between the thickness and width of portions, the proportions of sizes among portions, etc., are not necessarily the same as the actual values. Also, the dimensions and proportions may be illustrated differently among drawings, even when the same portion is illustrated.

In the specification and drawings, components similar to those described previously or illustrated in an antecedent drawing are marked with the same reference numerals, and a detailed description is omitted as appropriate.

### First Embodiment

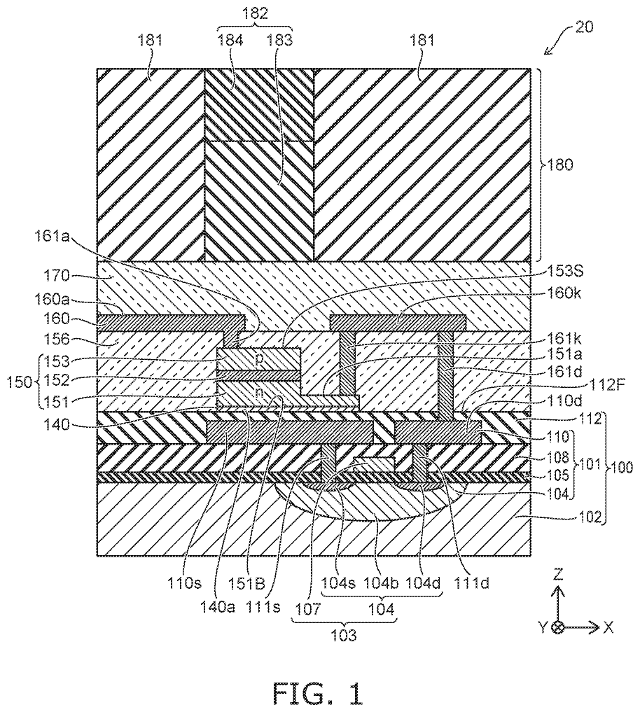

FIG. 1 is a schematic cross-sectional view illustrating a portion of an image display device according to the embodiment.

FIG. 1 schematically shows the configuration of a subpixel 20 of the image display device of the embodiment. A pixel that is included in an image displayed in the image display device includes multiple subpixels 20.

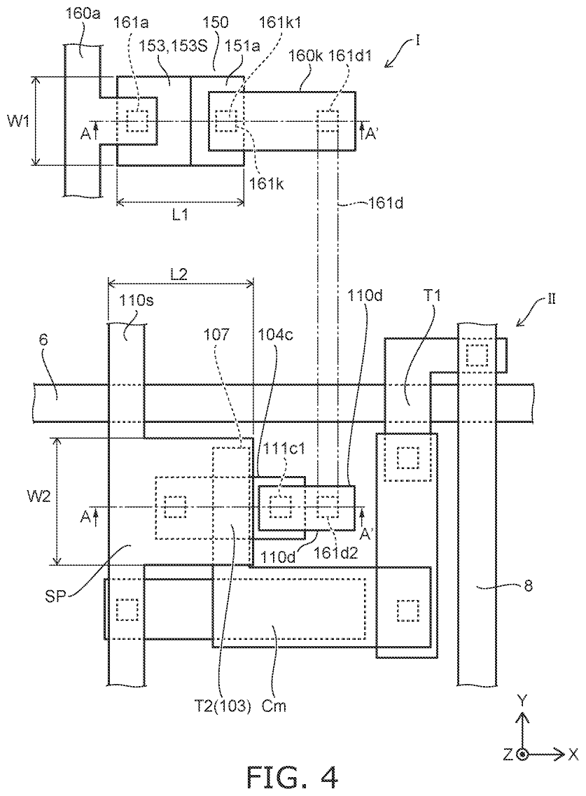

A right-handed XYZ three-dimensional coordinate system may be used in the following description. The subpixels 20 are arranged in a two-dimensional planar configuration. The two-dimensional plane in which the subpixels 20 are arranged is taken as an XY plane. The subpixels 20 are arranged along an X-axis direction and a Y-axis direction. FIG. 1 is an auxiliary cross section along line A-A′ of FIG. 4 below. Although the positive direction of the Z-axis may be called “up” or “above” and the negative direction of the Z-axis may be called “down” or “below” for convenience, directions along the Z-axis are not necessarily directions in which gravity acts. A length in a direction along the Z-axis may be called a height.

The subpixel 20 includes a light-emitting surface 153S that is substantially parallel to the XY plane. The light-emitting surface 153S is a surface that radiates light mainly toward the positive direction of the Z-axis orthogonal to the XY plane.

As shown in FIG. 1, the subpixel 20 of the image display device includes a transistor (a circuit element) 103, a first wiring layer 110, a first inter-layer insulating film (a first insulating film) 112, a graphene layer 140, a light-emitting element 150, a second inter-layer insulating film (a second insulating film) 156, a second wiring layer 160, and a via (a first via) 161d.

The subpixel 20 further includes a color filter 180. The color filter (the wavelength conversion member) 180 is located on a surface resin layer 170. It is favorable for the color filter 180 to be directly formed on the surface resin layer 170 by inkjet printing as in the example. When a film in which the color filter is formed is adhered instead of an inkjet technique, a transparent thin film adhesive layer is located between the surface resin layer and the color filter. The surface resin layer 170 is located on the second inter-layer insulating film 156 and wiring parts 160a and 160k.

The configuration of the subpixel 20 will now be described in detail.

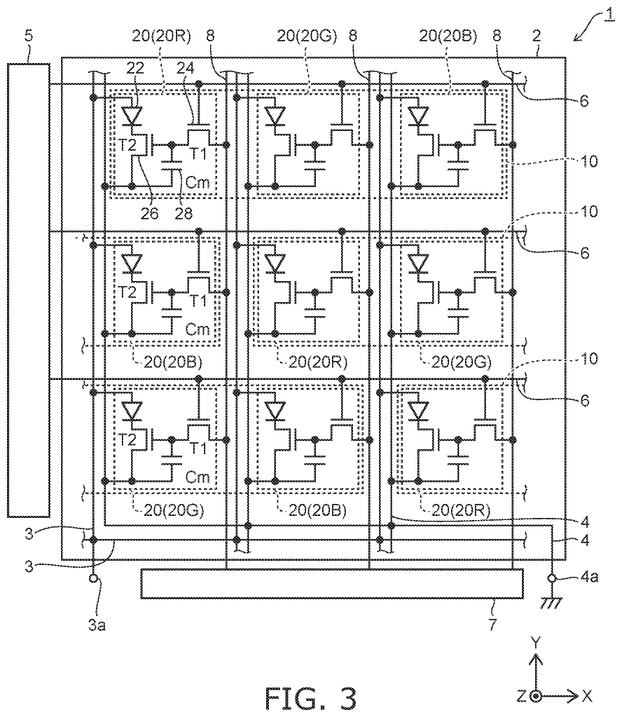

The transistor 103 is formed in a substrate 102. In addition to the drive transistor 103 of the light-emitting element 150, other circuit elements such as transistors, capacitors, etc., are formed in the substrate 102, and a circuit 101 is configured using wiring parts, etc. For example, the transistor 103 corresponds to a drive transistor 26 shown in FIG. 3 below, and a select transistor 24, a capacitor 28, etc., also are circuit elements.

In the following description, the circuit 101 includes an element formation region 104 in which circuit elements are formed, an insulating layer 105, the first wiring layer 110, vias 111d and 111s, and an insulating film 108. The vias 111s and 111d electrically connect the first wiring layer 110 and circuit elements including the transistor 103. The insulating film 108 electrically isolates the first wiring layer 110 and the circuit element and electrically isolates between the circuit elements, etc. Other components such as the substrate 102, the circuit 101, the first inter-layer insulating film 112, etc., also may be included when referring to a circuit board 100.

The transistor 103 includes a p-type semiconductor region 104b, n-type semiconductor regions 104s and 104d, and a gate 107. The gate 107 is located on the p-type semiconductor region 104b with the insulating layer 105 interposed. The insulating layer 105 is provided to insulate the element formation region 104 and the gate 107 and to sufficiently insulate from the other adjacent circuit elements. A channel may be formed in the p-type semiconductor region 104b when a voltage is applied to the gate 107. The transistor 103 is an n-channel transistor, e.g., an n-channel MOSFET.

The element formation region 104 is located in the substrate 102. The substrate 102 is a semiconductor substrate, e.g., a Si substrate. The element formation region 104 is formed from the surface of the substrate 102 in the depth direction of the substrate 102, i.e., the negative direction of the Z-axis. The element formation region 104 includes the p-type semiconductor region 104b and the n-type semiconductor regions 104s and 104d. The n-type semiconductor regions 104s and 104d are located at the surface vicinity of the element formation region 104 and are separated from each other. The p-type semiconductor region 104b is formed to surround the peripheries of the n-type semiconductor regions 104s and 104d and is located between the n-type semiconductor regions 104s and 104d when projected onto the XY plane. The p-type semiconductor region 104b also is formed below the n-type semiconductor regions 104s and 104d.

The insulating layer 105 is located on the substrate 102. The insulating layer 105 also covers the element formation region 104, and covers the p-type semiconductor region 104b and the n-type semiconductor regions 104s and 104d. The insulating layer 105 is, for example, SiO₂. The insulating layer 105 may be a multilevel insulating layer that includes SiO₂, Si₃N₄, etc., according to the covered region. The insulating layer 105 may further include a layer of an insulating material that has a high dielectric constant.

The gate 107 is located on the p-type semiconductor region 104b with the insulating layer 105 interposed. The gate 107 is located between the n-type semiconductor regions 104s and 104d. The gate 107 is, for example, polycrystalline Si. The gate 107 may include a refractory metal such as W, Mo, or the like, a silicide, etc., that has a lower resistance than polycrystalline Si.

In the example, the gate 107 and the insulating layer 105 are covered with the insulating film 108. The insulating film 108 is, for example, SiO₂, Si₃N₄, etc. To planarize the surface when forming the first wiring layer 110, an organic insulating film such as PSG (Phosphorus Silicon Glass), BPSG (Boron Phosphorus Silicon Glass), etc., also may be provided.

The via 111s extends through the insulating film 108 and reach the n-type semiconductor region 104s. The via 111d extends through the insulating film 108 and reach the n-type semiconductor region 104d. The first wiring layer 110 is formed on the insulating film 108. The first wiring layer 110 includes multiple wiring parts that can have different potentials and includes wiring parts 110s and 110d. For example, the wiring part 110s is connected to a ground line 4 of FIG. 3. The wiring part 110d is connected to the light-emitting element 150 by a via or the like as described below.

In FIG. 1 and subsequent cross-sectional views, unless otherwise noted, the reference numeral of a wiring layer to be marked is displayed at a position beside one wiring part included in the wiring layer with the reference numeral.

The via 111s is located between the wiring part 110s and the n-type semiconductor region 104s and electrically connects the wiring part 110s and the n-type semiconductor region 104s. The via 111d is located between the wiring part 110d and the n-type semiconductor region 104d and electrically connects the wiring part 110d and the n-type semiconductor region 104d. For example, the first wiring layer 110 and the vias 111s and 111d are formed of a metal such as Al, Cu, etc. The first wiring layer 110 and the vias 111s and 111d may include a refractory metal, etc.

The first wiring layer 110 can be utilized to shield the scattered light from the light-emitting element 150 in addition to being used as the electrical connection between circuit elements, to the upper structure of the light-emitting element 150 and the like formed on the circuit board 100, to the external circuit, etc. In the example, by providing the wiring part 110s between the light-emitting element 150 and the transistor 103, the wiring part 110s can function as a light-shielding plate for the transistor 103. In such a case, when projected onto the XY plane, the outer perimeter of the wiring part 110s is set to include the outer perimeter of the light-emitting element 150 when the light-emitting element 150 is projected onto the wiring part 110s. That is, the outer perimeter of the light-emitting element 150 is located within the outer perimeter of the wiring part 110s when projected onto the XY plane.

Although the wiring part 110s is utilized as a light-shielding plate in the example, another wiring part of the first wiring layer 110 may be utilized as a light-shielding plate, and the wiring part that is utilized as the light-shielding plate may or may not be connected to some potential.

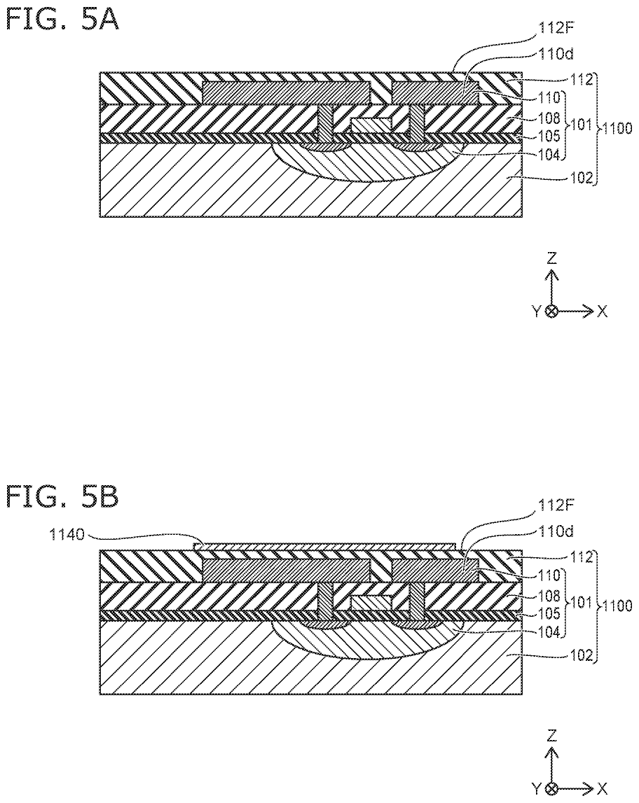

The first inter-layer insulating film 112 is located on the insulating film 108 and the first wiring layer 110. The first inter-layer insulating film 112 functions as a planarization film that includes a planarized surface 112F for the graphene layer 140 located on the first inter-layer insulating film 112. The graphene layer 140 includes a graphene sheet 140a, and the planarized surface 112F is flat enough that the graphene sheet 140a can be adhered. The first inter-layer insulating film 112 also functions as a protective film that protects the surface of a wafer 1100 shown in FIG. 5A below in storage, transportation, etc. The first inter-layer insulating film 112 is, for example, an organic insulating film of PSG, BPSG, etc.

The graphene layer 140 is located on the planarized surface 112F. The graphene layer 140 includes the graphene sheet (a first part) 140a. The graphene layer 140 includes multiple graphene sheets 140a, and the graphene sheets 140a are provided respectively for the light-emitting elements 150.

The outer perimeter of the graphene sheet 140a substantially matches the outer perimeter of the light-emitting element 150 when projected onto the XY plane. For example, the graphene layer 140 and the graphene sheet 140a are layered bodies in which several layers to about 10 layers of single-layer graphene are stacked.

The light-emitting element 150 includes a bottom surface 151B and the light-emitting surface 153S. The light-emitting element 150 is a prismatic or cylindrical element including the bottom surface 151B on the graphene sheet 140a. The light-emitting surface 153S is the surface at the side opposite to the bottom surface 151B.

The light-emitting element 150 includes an n-type semiconductor layer 151, a light-emitting layer 152, and a p-type semiconductor layer 153. The n-type semiconductor layer 151, the light-emitting layer 152, and the p-type semiconductor layer 153 are stacked in this order from the bottom surface 151B toward the light-emitting surface 153S.

The n-type semiconductor layer 151 includes a connection part 151a. For example, the connection part 151a is provided to protrude in one direction together with the graphene sheet 140a over the planarized surface 112F from the n-type semiconductor layer 151. The protrusion direction is not limited to one direction and may be two or more directions, or the protrusion may be provided over the entire perimeter of the n-type semiconductor layer 151. The height of the connection part 151a is the same as the height of the n-type semiconductor layer 151, or the light-emitting element 150 is formed in a staircase shape by setting the height of the connection part 151a to be less than the height of the n-type semiconductor layer 151. The connection part 151a is of the n-type and is electrically connected with the n-type semiconductor layer 151. In the example, the connection part 151a is provided to electrically connect a via 161k to the n-type semiconductor layer 151.

When the light-emitting element 150 is prismatic, the shape of the light-emitting element 150 when projected onto the XY plane is, for example, substantially square or rectangular. When the shape of the light-emitting element 150 when projected onto the XY plane is polygonal including quadrangular, the corner portions may be rounded. When the shape of the light-emitting element 150 when projected onto the XY plane is cylindrical, the shape of the light-emitting element 150 when projected onto the XY plane is not limited to circular and may be, for example, elliptical. The degree of freedom of the layout is increased by appropriately selecting the shape, arrangement, etc., of the light-emitting element when viewed in plan.

For example, the light-emitting element 150 favorably includes a gallium nitride compound semiconductor including a light-emitting layer of In_{X}Al_{Y}Ga_{1-X-Y}N (0≤X, 0≤Y, and X+Y<1), etc. Hereinbelow, the gallium nitride compound semiconductor may be called simply gallium nitride (GaN). According to an embodiment of the invention, the light-emitting element 150 is a so-called light-emitting diode. The wavelength of the light emitted by the light-emitting element 150 is, for example, about 467 nm±30 nm. The wavelength of the light emitted by the light-emitting element 150 may be a bluish-violet light emission of about 410 nm±30 nm. The wavelength of the light emitted by the light-emitting element 150 is not limited to these values and can be set as appropriate.

The areas of the light-emitting layers 152 when projected onto XY plane are set according to the light emission colors of the red, green, and blue subpixels. Hereinbelow, the area when projected onto the XY plane may be called simply the area. The area of the light-emitting layer 152 is appropriately set according to the luminous efficiency, the conversion efficiency of a color conversion part 182 of the color filter 180, etc. That is, the areas of the light-emitting layers 152 of the subpixels 20 of the light emission colors may be the same or may be different between the light emission colors. The area of the light-emitting layer 152 is the area of the region surrounded with the outer perimeter of the light-emitting layer 152 projected onto the XY plane.

Although the light-emitting element 150 is directly provided on the graphene sheet 140a in the example, a buffer layer may be located between the light-emitting element 150 and the graphene sheet 140a. The buffer layer is mainly used to promote growth of the semiconductor layer for forming the light-emitting element 150.

The second inter-layer insulating film 156 covers the planarized surface 112F, the graphene layer 140 including the graphene sheet 140a, and the light-emitting element 150. The second inter-layer insulating film 156 covers the light-emitting surface 153S and the side surface of the light-emitting element 150 and protects the light-emitting element 150. By being located between the adjacent light-emitting elements 150, the second inter-layer insulating film 156 functions as an insulating material that separates the light-emitting elements 150 from each other. The second inter-layer insulating film 156 provides a planarized surface for forming the second wiring layer 160. It is sufficient for the second inter-layer insulating film 156 to be flat enough that the second wiring layer 160 can be formed.

The second inter-layer insulating film 156 is formed of an organic insulating material. The organic insulating material that is included in the second inter-layer insulating film 156 is light-transmissive, and is favorably a transparent resin. A silicon resin such as SOG or the like, a novolak phenolic resin, etc., may be used as the transparent resin material.

The via (the first via) 161d extends through the second and first inter-layer insulating films 156 and 112, reach the wiring part 110d. One end of the via 161d is connected to the wiring part 110d, and the via 161d is electrically connected to the wiring part 110d.

The via (the second via) 161k extends through the second inter-layer insulating film 156 and reach the connection part 151a. One end of the via 161k is connected to the connection part 151a, and the via 161k is electrically connected to the n-type semiconductor layer 151 via the connection part 151a.

The second wiring layer 160 is located on the second inter-layer insulating film 156. The second wiring layer 160 includes the wiring parts 160a and 160k. A portion of the wiring part 160a is located above the light-emitting surface 153S and the surface including the light-emitting surface 153S. The wiring part 160a is electrically connected to the p-type semiconductor layer 153 via a connection member 161a connected to the surface including the light-emitting surface 153S. For example, the wiring part 160a is connected to a power supply line 3 shown in the circuit of FIG. 3 below.

The wiring part 160k is connected to the other ends of the vias 161k and 161d. That is, the via 161d is located between the wiring part 160k and the wiring part 110d and electrically connects the wiring part 160k and the wiring part 110d. The via 161k is located between the wiring part 160k and the connection part 151a and electrically connects the wiring part 160k and the connection part 151a. Accordingly, the n-type semiconductor layer 151 is electrically connected to the wiring part 110d via the connection part 151a, the via 161k, the wiring part 160k, and the via 161d.

Thus, for example, the p-type semiconductor layer 153 is electrically connected to the power supply line 3 shown in the circuit of FIG. 3 via the connection member 161a and the wiring part 160a. The n-type semiconductor layer 151 is electrically connected to the n-type semiconductor region 104d, i.e., the drain electrode of the transistor 103 via the connection part 151a, the via 161k, the wiring part 160k, the via 161d, the wiring part 110d, and the via 111d.

The surface resin layer 170 covers the second inter-layer insulating film 156 and the second wiring layer 160. The surface resin layer 170 is a transparent resin, protects the second inter-layer insulating film 156 and the second wiring layer 160, and includes a planarized surface for forming the color filter 180.

The color filter 180 includes a light-shielding part 181 and the color conversion part 182. The color conversion part 182 is located directly above the light-emitting surface 153S of the light-emitting element 150 to correspond to the shape of the light-emitting surface 153S. The portion of the color filter 180 other than the color conversion part 182 is used as the light-shielding part 181. The light-shielding part 181 is a so-called black matrix that reduces blur due to color mixing of the light emitted from the adjacent color conversion parts 182, etc., and makes it possible to display a sharp image.

The color conversion part 182 has one, two, or more layers. FIG. 1 shows a case where the color conversion part 182 has two layers. Whether the color conversion part 182 has one layer or two layers is determined by the color, i.e., the wavelength, of the light emitted by the subpixel 20. When the light emission color of the subpixel 20 is red, it is favorable for the color conversion part 182 to have the two layers of a color conversion layer 183 and a filter layer 184 that transmits red light. When the light emission color of the subpixel 20 is green, it is favorable for the color conversion part 182 to have the two layers of the color conversion layer 183 and the filter layer 184 that transmits green light. When the light emission color of the subpixel 20 is blue, it is favorable to use one layer.

When the color conversion part 182 has two layers, the first layer is the color conversion layer 183, and the second layer is the filter layer 184. The color conversion layer 183 of the first layer is located at a position more proximate to the light-emitting element 150. The filter layer 184 is stacked on the color conversion layer 183.

The color conversion layer 183 converts the wavelength of the light emitted by the light-emitting element 150 into the desired wavelength. When the subpixel 20 emits red, for example, the light of the wavelength of the light-emitting element 150, i.e., 467 nm±30 nm, is converted into light of a wavelength of about 630 nm±20 nm. When the subpixel 20 emits green, for example, the light of the wavelength of the light-emitting element 150, i.e., 467 nm±30 nm, is converted into light of a wavelength of about 532 nm±20 nm.

The filter layer 184 shields the wavelength component of the blue light emission that remains without undergoing color conversion by the color conversion layer 183.

When the color of the light emitted by the subpixel 20 is blue, the light-emitting element 150 may output the light via the color conversion layer 183, or may output the light as-is without the light passing through the color conversion layer 183. When the wavelength of the light emitted by the light-emitting element 150 is about 467 nm±30 nm, the light may be output without passing through the color conversion layer 183. When the wavelength of the light emitted by the light-emitting element 150 is 410 nm±30 nm, it is favorable to provide a one-layer color conversion layer 183 to convert the wavelength of the output light into about 467 nm±30 nm.

The subpixel 20 may include the filter layer 184 even when the subpixel 20 is blue. By providing the filter layer 184 through which blue light passes in the blue subpixel 20, the occurrence of a micro external light reflection other than blue light at the surface of the light-emitting element 150 is suppressed.

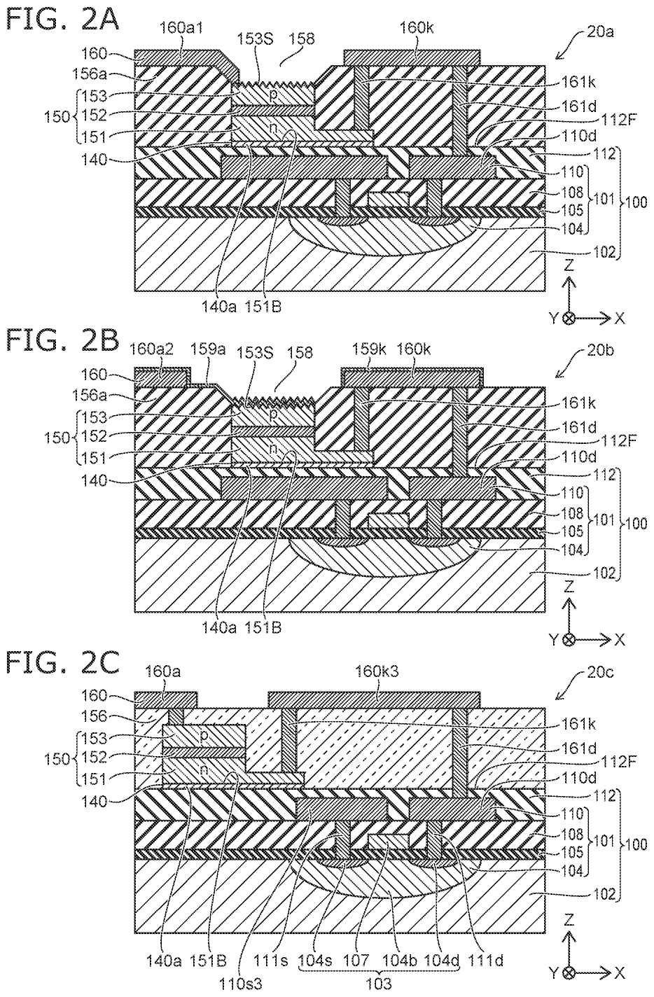

FIGS. 2A to 2C are cross-sectional views schematically showing portions of image display devices according to modifications of the embodiment.

The examples shown in FIGS. 2A and 2B different from the first embodiment described above in that a portion of a second inter-layer insulating film 156a on the light-emitting surface 153S is removed, and the light-emitting surface 153S is exposed from under the second inter-layer insulating film 156a. The method of the electrical connection to the light-emitting surface 153S also is different from that of the first embodiment. The same components are marked with the same reference numerals, and a detailed description is omitted as appropriate.

Although not illustrated to avoid complexity of illustration in FIGS. 2A to 2C, the structure of the surface resin layer 170 and higher shown in FIG. 1 is the same as that of the first embodiment.

In a subpixel 20a as shown in FIG. 2A, the second wiring layer 160 includes a wiring part 160a1. One end of the wiring part 160a1 is provided to reach the surface including the light-emitting surface 153S. According to the modification, for example, the light-emitting surface 153S is electrically connected to the power supply line 3 shown in the circuit of FIG. 3 via the wiring part 160a1. The light-emitting surface 153S may be roughened as in the example or may not be roughened. When the light-emitting surface 153S is roughened, the light extraction efficiency can be increased. When not roughened, the process for roughening can be omitted.

The second inter-layer insulating film 156a covers the planarized surface 112F and the side surface of the light-emitting element 150. The second inter-layer insulating film 156a is formed of a light-reflective material, and is favorably formed of a white resin.

The white resin is formed by dispersing fine scattering particles having a Mie scattering effect in a silicon resin such as SOG (Spin On Glass) or the like, a transparent resin such as a novolak phenolic resin, etc. The fine scattering particles are colorless or white and have a diameter of about 1/10 to about several times the wavelength of the light emitted by the light-emitting element 150. The fine scattering particles that are favorably used have a diameter of about ½ of the light wavelength. For example, TiO₂, Al₂O₃, ZnO, etc., are examples of such a fine scattering particle.

The white resin also can be formed by utilizing many fine voids or the like dispersed in a transparent resin. When whitening the second inter-layer insulating film 156a, for example, a SiO₂ film or the like that is formed by ALD (Atomic-Layer-Deposition) or CVD may be used instead of SOG, etc.

The second inter-layer insulating film 156a may be formed of a black resin. By using a black resin as the second inter-layer insulating film 156a, the scattering of the light inside the subpixel 20 is suppressed, and stray light is more effectively suppressed. An image display device in which stray light is suppressed can display a sharper image.

A portion of the second inter-layer insulating film 156a is removed to form an opening 158 that exposes the light-emitting surface 153S from under the second inter-layer insulating film 156a. The second wiring layer 160 includes the wiring part 160a1, and one end of the wiring part 160a1 is connected to the surface including the light-emitting surface 153S. For example, the wiring part 160a1 is connected to the power supply line 3 shown in FIG. 3.

In a subpixel 20b as shown in FIG. 2B, similarly to the example shown in FIG. 2A, a portion of the second inter-layer insulating film 156a is removed to form the opening 158 that exposes the light-emitting surface 153S from under the second inter-layer insulating film 156a. The second wiring layer 160 includes a wiring part 160a2. The wiring part 160a2 is located at a position separated from the light-emitting surface 153S. For example, the wiring part 160a2 is connected to the power supply line 3 of the circuit shown in FIG. 3.

A light-transmitting electrode 159a is provided over the wiring part 160a2. The light-transmitting electrode 159a is provided over the light-emitting surface 153S. The light-transmitting electrode 159a also is located between the wiring part 160a2 and the light-emitting surface 153S and electrically connects the wiring part 160a2 and the light-emitting surface 153S. A light-transmitting electrode 159k is provided over the wiring part 160k.

The light-transmitting electrodes 159a and 159k are formed of light-transmitting conductive films. The light-transmitting conductive films favorably include an ITO film, a ZnO film, etc. Because the light-transmitting electrode 159a is provided over the light-emitting surface 153S, the connection area with the light-emitting surface 153S can be increased, the contact resistance can be reduced, and the luminous efficiency of the light-emitting element 150 can be substantially improved.

FIG. 2C shows when the positions in the XY plane of the light-emitting element 150 and the circuit elements such as the transistor 103, etc., are shifted from each other. For the following reasons, there are cases where the light-emitting element 150 and the transistor 103 are located not to overlap each other when viewed in plan. There are cases where a depletion layer region is generated between the p-type semiconductor region 104b and the n-type substrate 102, and the depletion layer region functions as a parasitic photodiode. It is favorable for the parasitic photodiode not to overlap the light irradiation region occurring directly under the light-emitting element 150. In such a case, when projected onto the XY plane, it is favorable to set the distance between the end portion and the boundary of the p-type semiconductor region 104b to be at least not less than about 1 μm when the light-emitting layer 152 is projected onto the surface of the substrate 102.

In a subpixel 20c as shown in FIG. 2C, the first wiring layer 110 includes a wiring part 110s3, and the wiring part 110s3 is provided to be separated from the position at which the light-emitting element 150 is placed. That is, when projected onto the XY plane, the wiring part 110s3 is not always include the outer perimeter portion of the light-emitting element 150 when projected from above in the Z-axis. On the other hand, the length in the X-axis direction of a wiring part 160k3 is longer than those of the embodiment and other modifications described above.

Thus, when the light-emitting element 150 is sufficiently separated from the circuit element, malfunction due to light does not easily occur because the circuit element receives little of the light scattered in the negative direction of the Z-axis. Thus, when the wiring part of the first wiring layer 110 is not used to shield, the degree of freedom of the circuit layout can be increased, and the integration density can be increased.

The embodiment can include any of the configurations of the subpixels 20, 20a, 20b, and 20c described above. Any of these subpixels also is applicable to the other embodiments described below and their modifications. In other words, the connection with the light-emitting surface 153S may be performed by a light-transmitting electrode or may be directly connected by the wiring part 160a1.

FIG. 3 is a schematic block diagram illustrating the image display device according to the embodiment.

As shown in FIG. 3, the image display device 1 of the embodiment includes a display region 2. The subpixels 20 are arranged in the display region 2. For example, the subpixels 20 are arranged in a lattice shape. For example, n subpixels 20 are arranged along the X-axis, and m subpixels 20 are arranged along the Y-axis.

A pixel 10 includes multiple subpixels 20 that emit light of different colors. A subpixel 20R emits red light. A subpixel 20G emits green light. A subpixel 20B emits blue light. The light emission color and luminance of one pixel 10 are determined by the three types of the subpixels 20R, 20G, and 20B emitting light of the desired luminances.

One pixel 10 includes the three subpixels 20R, 20G, and 20B; for example, the subpixels 20R, 20G, and 20B are arranged in a straight line along the X-axis as shown in FIG. 3. In each pixel 10, subpixels of the same color may be arranged in the same column, or subpixels of different colors may be arranged in each column as in the example.

The image display device 1 further includes the power supply line 3 and the ground line 4. The power supply line 3 and the ground line 4 are wired in a lattice shape along the arrangement of the subpixels 20. The power supply line 3 and the ground line 4 are electrically connected to each subpixel 20, and electrical power is supplied to each subpixel 20 from a DC power supply connected between a power supply terminal 3a and the GND terminal 4a. The power supply terminal 3a and the GND terminal 4a are located respectively at end portions of the power supply line 3 and the ground line 4, and are connected to a DC power supply circuit located outside the display region 2. The power supply terminal 3a supplies a positive voltage when referenced to the GND terminal 4a.

The image display device 1 further includes a scanning line 6 and a signal line 8. The scanning line 6 is wired in a direction parallel to the X-axis. That is, the scanning lines 6 are wired along the arrangement in the row direction of the subpixels 20. The signal line 8 is wired in a direction parallel to the Y-axis. That is, the signal lines 8 are wired along the arrangement in the column direction of the subpixels 20.

The image display device 1 further includes a row selection circuit 5 and a signal voltage output circuit 7. The row selection circuit 5 and the signal voltage output circuit 7 are located along the outer edge of the display region 2. The row selection circuit 5 is located along the outer edge of the display region 2 in the Y-axis direction. The row selection circuit 5 is electrically connected to the subpixel 20 of each column via the scanning line 6, and supplies a select signal to each subpixel 20.

The signal voltage output circuit 7 is located along the outer edge of the display region 2 in the X-axis direction. The signal voltage output circuit 7 is electrically connected to the subpixel 20 of each row via the signal line 8, and supplies a signal voltage to each subpixel 20.

The subpixel 20 includes a light-emitting element 22, the select transistor 24, the drive transistor 26, and the capacitor 28. In FIGS. 3 and 4 below, the select transistor 24 may be displayed as T1, the drive transistor 26 may be displayed as T2, and the capacitor 28 may be displayed as Cm.

The light-emitting element 22 is connected in series with the drive transistor 26. According to the embodiment, the drive transistor 26 is an n-channel transistor, and the cathode electrode of the light-emitting element 22 is connected to the drain electrode of the drive transistor 26. Major electrodes of the drive transistor 26 and the select transistor 24 are drain electrodes and source electrodes. The anode electrode of the light-emitting element 22 is located at the p-type semiconductor layer. The cathode electrode of the light-emitting element is located at the n-type semiconductor layer. A series circuit of the light-emitting element 22 and the drive transistor 26 is connected between the power supply line 3 and the ground line 4. The drive transistor 26 corresponds to the transistor 103 of FIG. 1, and the light-emitting element 22 corresponds to the light-emitting element 150 of FIG. 1. The current that flows in the light-emitting element 22 is determined by the voltage applied between the gate and source of the drive transistor 26, and the light-emitting element 22 emits light of a luminance corresponding to the current that flows.

The select transistor 24 is connected between the signal line 8 and the gate electrode of the drive transistor 26 via a major electrode. The gate electrode of the select transistor 24 is connected to the scanning line 6. The capacitor 28 is connected between the power supply line 3 and the gate electrode of the drive transistor 26.

The row selection circuit 5 selects one row from the arrangement of m rows of the subpixels 20 and supplies a select signal to the scanning line 6. The signal voltage output circuit 7 supplies a signal voltage that has an analog voltage value necessary for each subpixel 20 of the selected row. The signal voltage is applied between the gate and source of the drive transistor 26 of the subpixels 20 of the selected row. The signal voltage is maintained by the capacitor 28. The drive transistor 26 allows a current corresponding to the signal voltage to flow in the light-emitting element 22. The light-emitting element 22 emits light of a luminance corresponding to the current flowing in the light-emitting element 22.

The row selection circuit 5 sequentially switches the row that is selected, and supplies the select signal. That is, the row selection circuit 5 scans through the rows in which the subpixels 20 are arranged. Light emission is performed by currents that correspond to the signal voltages flowing in the light-emitting elements 22 of the subpixels 20 that are sequentially scanned. An image is displayed in the display region 2 by each pixel 10 emitting the light emission color and luminance determined by the light emission color and luminance emitted by the subpixels 20 of the colors of RGB.

FIG. 4 is a schematic plan view illustrating a portion of the image display device of the embodiment.

According to the embodiment as described in reference to FIG. 1, the light-emitting element 150 and the drive transistor 103 are stacked in the Z-axis direction, and the cathode electrode of the light-emitting element 150 and the drain electrode of the drive transistor 103 are electrically connected using the via 161d, etc.

A plan view of an Ith layer is schematically displayed in the upper drawing of FIG. 4, and a plan view of an IIth layer is schematically displayed in the lower drawing of FIG. 4. In FIG. 4, the Ith layer is labeled “I”, and the IIth layer is labeled “II”. The Ith layer is a layer in which the light-emitting element 150 is formed. In other words, the Ith layer includes the layers from the graphene layer 140 to the second wiring layer 160 in the positive direction of the Z-axis in FIG. 1. The second inter-layer insulating film 156 is not shown in FIG. 4. The IIth layer includes the layers from the substrate 102 to the first inter-layer insulating film 112 in the positive direction of the Z-axis in FIG. 1. The substrate 102, the insulating layer 105, the insulating film 108, and the first inter-layer insulating film 112 are not shown in FIG. 4. A channel region 104c is shown as the element formation region 104 in these drawings.

The cross-sectional view shown in FIG. 1 is an auxiliary cross section along line A-A′ of FIG. 4 at the locations shown by the single dot-dash lines in each of the Ith layer and the IIth layer.

As shown in FIG. 4, the cathode electrode of the light-emitting element 150 is provided by the connection part 151a and connected to the wiring part 160k by the via 161k and a contact hole 161k1.

The wiring part 160k is connected to one end of the via 161d by a contact hole 161d1, and the other end of the via 161d is connected to the wiring part 110d via a contact hole 161d2.

The wiring part 110d is connected to the via 111d shown in FIG. 1 via a contact hole 111i1 made in the insulating film 108 shown in FIG. 1. The via 111d is connected to the n-type semiconductor region 104d shown in FIG. 1 formed in the channel region 104c. The n-type semiconductor region 104d provides the drain electrode of the transistor 103.

Thus, the light-emitting element 150 and the transistor 103 that are formed respectively in the Ith layer and the IIth layer which are different layers can be electrically connected by the via 161d extending through the second and first inter-layer insulating films 156 and 112. The via 161d is schematically shown by a double dot-dash line in FIG. 4.

The anode electrode of the light-emitting element 150 is provided by the p-type semiconductor layer 153. The surface that includes the light-emitting surface 153S is connected to the wiring part 160a via the connection member 161a.

The shape of the wiring part 110s when projected onto the XY plane will now be described using FIG. 4.

In the example, the light-emitting element 150 has a stepped rectangular parallelepiped shape including the bottom surface 151B shown in FIG. 1. The bottom surface 151B has a length L1 in the X-axis direction and a length W1 in the Y-axis direction.

In the example, the wiring part 110s includes a rectangular light-shielding plate (second part) SP, and the light-shielding plate SP has a length L2 in the X-axis direction and a length W2 in the Y-axis direction.

The lengths of the portions described above are set so that L2>L1 and W2>W1. The light-emitting element 150 is located directly above the light-shielding plate SP, and the outer perimeter of the light-shielding plate SP includes the outer perimeter of the light-emitting element 150 when projected onto the XY plane. That is, the outer perimeter of the light-emitting element 150 is located within the outer perimeter of the light-shielding plate SP. It is sufficient for the outer perimeter of the light-emitting element 150 to be within the outer perimeter of the light-shielding plate SP, and the shape of the light-shielding plate SP and the shape of the light-emitting element 150 are not limited to quadrangular and may be any appropriate shape.

In the light-emitting element 150, in addition to the upward light emission, there is also downward light emission, reflected light at the interface between the second inter-layer insulating film 156 and the surface resin layer 170 shown in FIG. 1, scattered light, etc. Accordingly, by setting the outer perimeter of the light-emitting element 150 to be within the outer perimeter of the light-shielding plate SP when projected onto the XY plane, malfunction of the circuit elements including the transistor 103 due to light, etc., can be suppressed.

A method for manufacturing the image display device 1 of the embodiment will now be described.

FIGS. 5A to 7 are schematic cross-sectional views illustrating the method for manufacturing the image display device of the embodiment.

The wafer (the substrate) 1100 is prepared according to the method for manufacturing the image display device of the embodiment as shown in FIG. 5A. The wafer 1100 includes the substrate 102, the circuit 101, and the first inter-layer insulating film 112. The circuit 101 is pre-formed in the substrate 102 formed of Si or the like, and the first inter-layer insulating film 112 that protects the circuit 101 and provides the planarized surface 112F is formed. The wafer 1100 is, for example, a disk-shaped member having a diameter of about 4 inches to 12 inches.

As shown in FIG. 5B, a graphene layer 1140 is formed on the planarized surface 112F. The graphene layer 1140 is a graphene-including layer, and is favorably a sheet-like member formed by stacking several layers to about 10 layers of a single-layer graphene layer. The graphene layer 1140 is cut to the appropriate size and shape, disposed at the prescribed position of the planarized surface 112F, and held by suction to the first inter-layer insulating film 112 by the flatness. For example, the graphene layer 1140 may be bonded on the planarized surface 112F by an adhesive, etc.

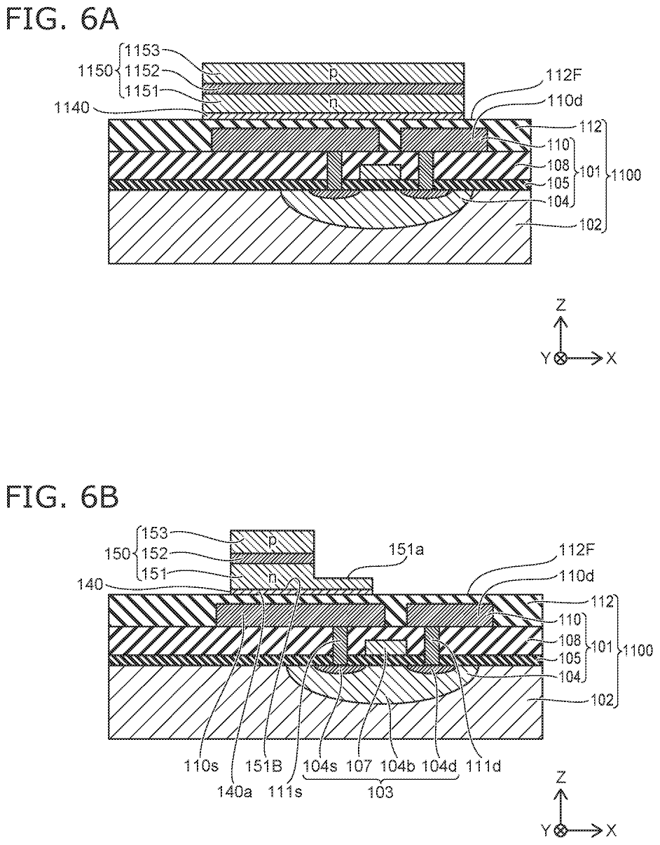

As shown in FIG. 6A, a semiconductor layer 1150 is formed over the graphene layer 1140. The semiconductor layer 1150 includes an n-type semiconductor layer 1151, a light-emitting layer 1152, and a p-type semiconductor layer 1153 formed in this order from the graphene layer 1140 in the positive direction of the Z-axis.

To form the semiconductor layer 1150 including a GaN crystal, physical vapor deposition such as vapor deposition, ion beam deposition, molecular beam epitaxy (MBE), sputtering, or the like is used, and it is favorable to use low-temperature sputtering. Low-temperature sputtering is favorable because a lower temperature when forming is possible by assisting with light and/or plasma. There are cases where 1000° C. is exceeded in epitaxial growth by MOCVD. In contrast, it is known that a GaN crystal including a light-emitting layer can be epitaxially grown on the single-crystal metal layer in low-temperature sputtering at a low temperature of about 400° C. to about 700° C. (see Non-Patent Literature 1 and 2, etc.). Such low-temperature sputtering is effective for increasing the yield of wafer processing for larger diameters.

Thus, it is desirable for the planarized surface 112F to have sufficient flatness because the graphene layer 1140 is formed on the planarized surface 112F, and crystal growth of the semiconductor layer 1150 on the graphene layer 1140 is performed.

By using appropriate film formation technology, the semiconductor layer 1150 that is monocrystallized and includes the light-emitting layer 1152 is formed on the graphene layer 1140 by growing the GaN semiconductor layer 1150 on the graphene layer 1140. Although not illustrated, there are also cases where amorphous deposits that include materials of the growth species such as Ga are deposited at locations at which the graphene layer 1140 does not exist in the growth process of the semiconductor layer 1150.

According to the embodiment, the crystal formation of GaN is promoted by using the graphene layer 1140 as a seed. When using a buffer layer to further promote the growth of the semiconductor layer 1150, for example, the buffer layer is formed on the graphene layer 1140 by physical vapor deposition such as sputtering, etc. The buffer layer can be any type of material that promotes GaN crystal growth, and may be an insulating material or a conductive material such as a metal, etc. For example, a metal layer that includes a single crystal of Hf, Cu, etc., may be used as the buffer layer.

According to the embodiment, the semiconductor layer 1150 is formed on the graphene layer 1140 from the n-type semiconductor layer 1151. In the initial growth of the semiconductor layer 1150, crystal defects caused by crystal lattice mismatch easily occur, and crystals having GaN as a major component generally have n-type semiconductor characteristics. Therefore, the yield can be increased by growing the semiconductor layer 1150 from the n-type semiconductor layer 1151 on the graphene layer 1140.

As shown in FIG. 6B, the light-emitting element 150 is formed by patterning the semiconductor layer 1150 shown in FIG. 6A into the desired shape by etching, etc. The connection part 151a is formed in the formation process of the light-emitting element 150, and then the other parts are formed by further etching. The light-emitting element 150 that includes the connection part 151a protruding in one direction from the n-type semiconductor layer 151 over the planarized surface 112F can be formed thereby.

To form the light-emitting element 150, for example, a dry etching process is used, and it is favorable to use anisotropic plasma etching (Reactive Ion Etching (RIE)). When deposits are formed at locations at which the graphene layer 1140 does not exist, the formed deposits are removed in the etching process of forming the light-emitting element 150.

In the formation process of the connection part 151a, the graphene layer 1140 shown in FIG. 6A is shaped by over etching into the graphene sheet 140a having an outer perimeter shape that substantially matches the outer perimeter shape of the bottom surface 151B of the light-emitting element 150. The outer perimeter of the bottom surface 151B includes the outer perimeters of the n-type semiconductor layer 151 and the connection part 151a.

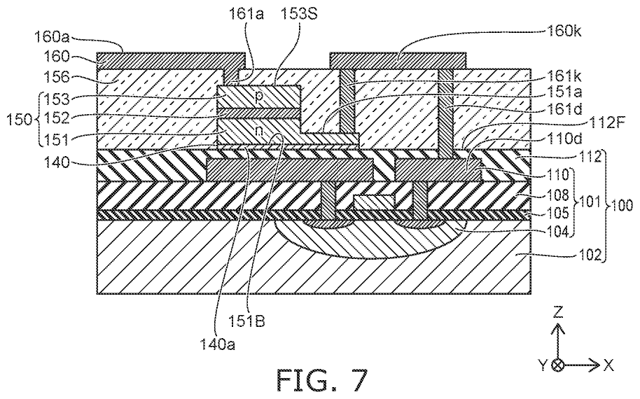

As shown in FIG. 7, the second inter-layer insulating film (the second insulating film) 156 is formed to cover the planarized surface 112F, the graphene layer 140 including the graphene sheet 140a, and the light-emitting element 150.

A via hole that is formed to extend through the second and first inter-layer insulating films 156 and 112 and reach the wiring part 110d is filled with a conductive material to form the via (the first via) 161d. A via hole that is formed to extend through the second inter-layer insulating film 156 and reach the connection part 151a is filled with a conductive material to form the via (the second via) 161k.

A contact hole that is formed in the second inter-layer insulating film 156 on the surface including the light-emitting surface 153S is filled with a conductive material to form the connection member 161a.

The second wiring layer 160 that includes the wiring parts 160a and 160k is formed on the second inter-layer insulating film 156. The wiring part 160k is connected with the vias 161d and 161k. The wiring part 160a is connected with the connection member 161a. The formation process of the second wiring layer 160 may include the formation process of the vias 161k and 161d and the connection member 161a or may be performed after forming the vias 161k and 161d and the connection member 161a.

Thereafter, the subpixel 20 of the image display device of the embodiment is formed by providing a color filter, etc.

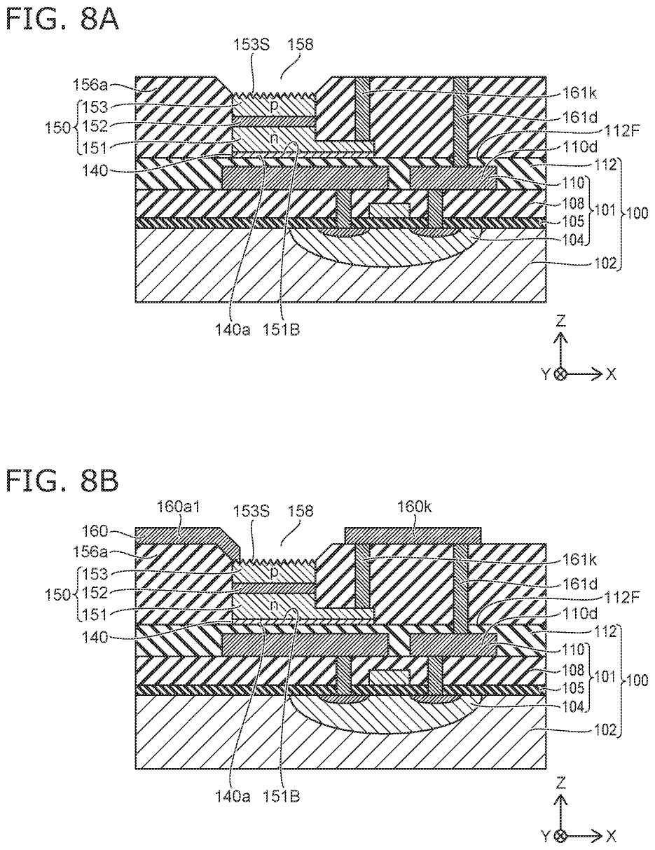

FIGS. 8A and 8B are schematic cross-sectional views illustrating a manufacturing method of a modification of the image display device of the embodiment.

FIG. 8A shows a portion of processes of forming the subpixel 20a shown in FIG. 2A. Because the modification differs from the first embodiment in that the opening 158 is formed and the shape of the wiring part 160a1 is different, the same processes as the first embodiment are applied up to the process described in reference to FIG. 6B. The process of FIG. 8A is performed after performing the process of FIG. 6B.

As shown in FIG. 8A, the second inter-layer insulating film 156a is formed to cover the planarized surface 112F, the graphene layer 140 including the graphene sheet 140a, and the light-emitting element 150.

The opening 158 is formed by removing a portion of the second inter-layer insulating film 156a on the surface including the light-emitting surface 153S. The light-emitting surface 153S is exposed from under the second inter-layer insulating film 156a via the opening 158. In the example, the surface that includes the exposed light-emitting surface 153S is roughened.

A via hole that is formed to extend through the second and first inter-layer insulating films 156a and 112 and reach the wiring part 110d is filled with a conductive material to form the via 161d. A via hole that is formed to extend through the second inter-layer insulating film 156a and reach the connection part 151a is filled with a conductive material to form the via 161k.

As shown in FIG. 8B, the second wiring layer 160 that includes the wiring parts 160a1 and 160k is formed on the second inter-layer insulating film 156a. In the formation process of the second wiring layer 160, one end of the wiring part 160a1 is formed to be connected to the surface including the light-emitting surface 153S. The surface that includes the light-emitting surface 153S includes the surface at which the light-emitting surface 153S and the one end of the wiring part 160a1 are connected.

The wiring part 160k is formed in the same shape as that of the first embodiment. Similarly to the first embodiment, the vias 161d and 161k may be simultaneously formed when forming the second wiring layer 160.

Thereafter, the subpixel 20a shown in FIG. 2A is formed by providing a color filter, etc.

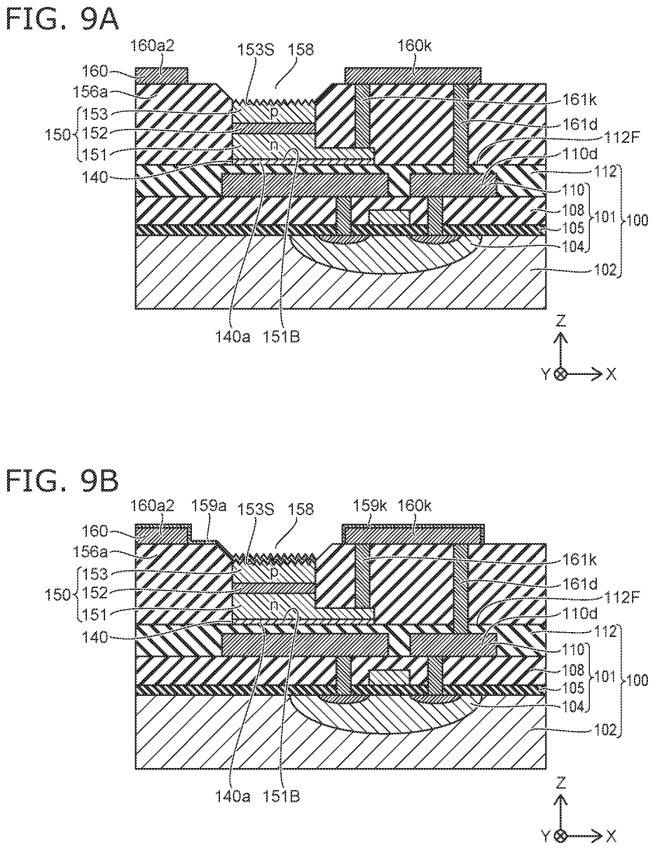

FIGS. 9A and 9B show a portion of processes of forming the subpixel 20b shown in FIG. 2B. The modification differs from the first embodiment and the modification shown in FIG. 2A in that the formation process of the light-transmitting electrodes 159a and 159k is included and the configuration of the wiring part 160a2 is different. The same processes as the modification up to the manufacturing process shown in FIG. 8A are applied to the modification. The process of FIG. 9A is described as being performed after performing the process of FIG. 8A.

As shown in FIG. 9A, the second wiring layer 160 that includes the wiring parts 160a2 and 160k is formed on the second inter-layer insulating film 156a. In the formation process of the wiring part 160a2, the wiring part 160a2 is formed at a position separated from the opening 158.

The light-transmitting electrodes 159a and 159k are formed as shown in FIG. 9B. The light-transmitting electrode 159a is formed over the light-emitting surface 153S and over the wiring part 160a2. Simultaneously, the light-transmitting electrode 159a also is formed between the light-emitting surface 153S and the wiring part 160a2 to electrically connect the light-emitting surface 153S and the wiring part 160a2. Thus, the wiring part 160a2 that is provided to be separated from the opening 158 is electrically connected to the light-emitting surface 153S by the light-transmitting electrode 159a. The light-transmitting electrode 159k is formed over the wiring part 160k.

Thereafter, the subpixel 20b shown in FIG. 2B is formed by providing a color filter, etc.

According to the modification shown in FIG. 2C, the shape of the wiring part 110s3 is different due to the different arrangement of the light-emitting element 150 and the transistor 103. The manufacturing processes of the wafer 1100 for the modification shown in FIG. 2C are the same as those of the first embodiment, and a detailed description is omitted.

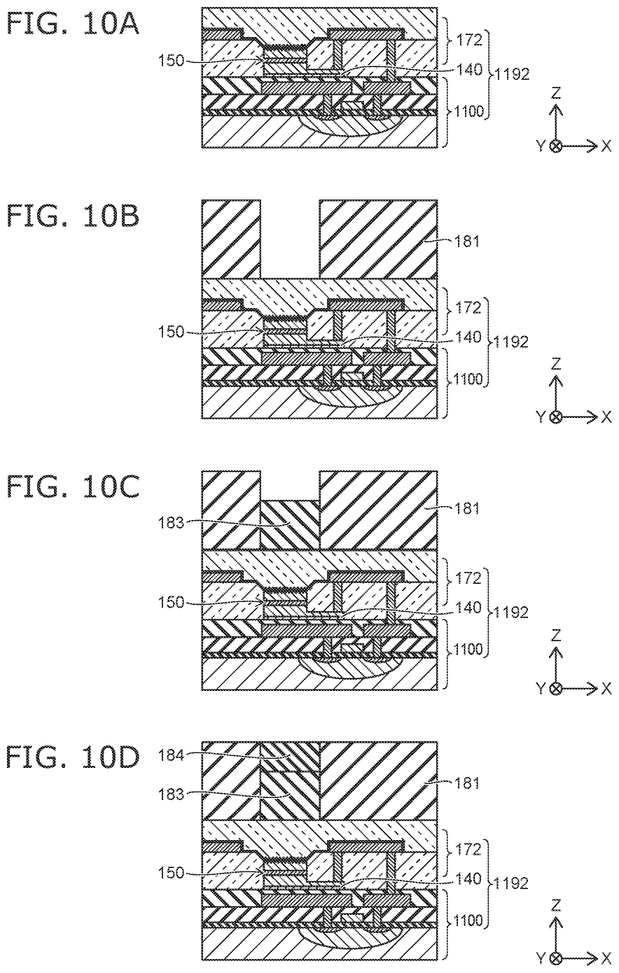

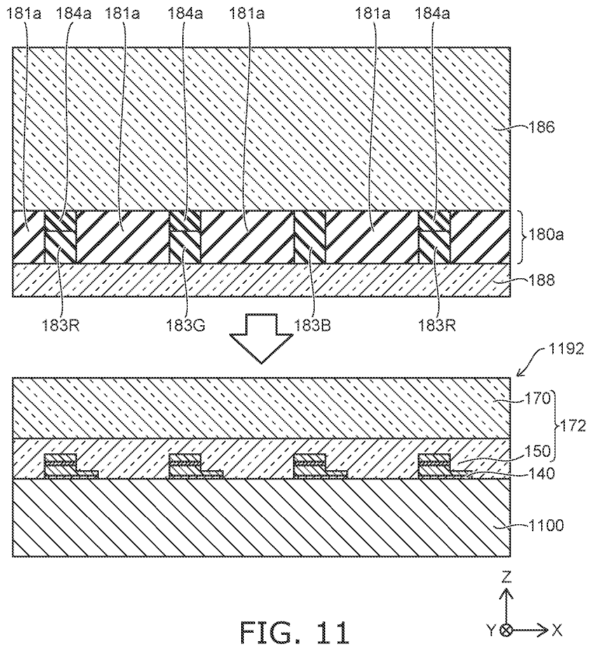

A formation process of the color filter 180 shown in FIG. 1 will now be described. In the description related to the formation process of the color filters 180 and FIG. 10A to FIGS. 10D and 11, the structural component that includes the light-emitting element 150, the second inter-layer insulating film 156, the vias 161d and 161k, the second wiring layer 160, and the surface resin layer 170 is called a light-emitting circuit part 172. The structural component that includes the wafer 1100, the graphene layer 140, and the light-emitting circuit part 172 is called a structure body 1192. The reference numerals other than the light-emitting element 150 are not illustrated in the light-emitting circuit part 172 of FIGS. 10A to 10D.

FIGS. 10A to 10D are schematic cross-sectional views showing the method for manufacturing the image display device of the embodiment.

FIGS. 10A to 10D show processes when the color filter (the wavelength conversion member) 180 shown in FIG. 1 is formed by inkjet printing.

As shown in FIG. 10A, the structure body 1192 in which the graphene layer 140 and the light-emitting circuit part 172 are formed on the wafer 1100 is prepared.

As shown in FIG. 10B, the light-shielding part 181 is formed on the structure body 1192. For example, the light-shielding part 181 is formed using screen printing, photolithography technology, etc.

As shown in FIG. 10C, the color conversion layer 183 is formed by dispensing a fluorescer that corresponds to the light emission color from an inkjet nozzle. The fluorescer colors the region in which the light-shielding part 181 is not formed. The fluorescer includes, for example, a fluorescent coating that uses a general fluorescer material, a perovskite fluorescer material, or a quantum dot fluorescer material. It is favorable to use a perovskite fluorescer material or a quantum dot fluorescer material because the light emission colors can be realized with high monochromaticity and high color reproducibility. After printing with the inkjet nozzle, drying processing is performed using an appropriate temperature and time. The thickness of the coating when coloring is set to be less than the thickness of the light-shielding part 181.

The color conversion layer 183 is not formed in the subpixel of blue light emission when the color conversion part is not formed. Also, when a blue color conversion layer is formed in the subpixel of blue light emission, and when the color conversion part may have one layer, it is favorable for the thickness of the coating of the blue fluorescer to be about equal to the thickness of the light-shielding part 181.

As shown in FIG. 10D, the coating for the filter layer 184 is dispensed from the inkjet nozzle. The coating is applied to overlap the coating of the fluorescer. The total thickness of the fluorescer and the coating is set to be about equal to the thickness of the light-shielding part 181. Thus, the color filter 180 is formed.

Instead of a color filter by inkjet printing, a process of forming a film-type color filter 180a will now be described.

FIG. 11 is a schematic cross-sectional view illustrating a modification of the method for manufacturing the image display device of the embodiment.

In FIG. 11, the drawing above the arrow shows a configuration that includes the color filter 180a, and the drawing below the arrow shows the structure body 1192 that includes the wafer 1100, the graphene layer 140, and the light-emitting circuit part 172 formed in the processes described above. The arrow of FIG. 11 indicates the process of bonding, to the structure body 1192, the color filter 180a that is formed in a film shape.

To avoid complexity in FIG. 11, the components inside the illustrated wafer 1100 and a portion of the components formed on the wafer 1100 are not illustrated. The components inside the wafer 1100 that are not illustrated are the substrate 102 shown in FIG. 1 and the circuit 101 that includes the first inter-layer insulating film 112, the element formation region 104, the first wiring layer 110, etc. The components of the light-emitting circuit part 172 that are not illustrated are the vias 161d and 161k and the second wiring layer 160.

As shown in FIG. 11, the color filter (the wavelength conversion member) 180a includes a light-shielding part 181a, color conversion layers 183R, 183G, and 183B, and a filter layer 184a. The light-shielding part 181a has a function similar to when an inkjet technique is used. The color conversion layers 183R, 183G, and 183B are formed to have functions and materials similar to when an inkjet technique is used. The filter layer 184a also has a function similar to when an inkjet technique is used.

The color filter 180a is bonded to the structure body 1192 at one surface. The other surface of the color filter 180a is bonded to a glass substrate 186. A transparent thin film adhesive layer 188 is located at the one surface of the color filter 180a, and the exposed surface of the surface resin layer 170 of the structure body 1192 is bonded to the one surface of the color filter 180a via the transparent thin film adhesive layer 188.

In the color filter 180a of the example, color conversion parts are arranged in the positive direction of the X-axis in the order of red, green, and blue. For red, a red color conversion layer 183R is located in the first layer; for green, a green color conversion layer 183G is located in the first layer, and the filter layer 184a is located in the second layer for both red and green. For blue, a single-layer color conversion layer 183B may be provided, and the filter layer 184a may be provided. The light-shielding part 181a is located between the color conversion parts, and it goes without saying that the frequency characteristics of the filter layer 184 can be modified for each color of the color conversion parts.

The color filter 180a is adhered to the structure body 1192 so that the positions of the color conversion layers 183R, 183G, and 183B of each color match the positions of the light-emitting elements 150.

Thus, the color filters 180 and 180a are formed in the structure body 1192 including the light-emitting circuit part 172, etc., and the subpixels are formed. An appropriate technique for the color filter is selected among inkjet techniques, film techniques, and other techniques that can form an equivalent color filter. By forming the color filter 180 by inkjet printing, the film adhesion process, etc., can be omitted, and the image display device 1 can be manufactured more inexpensively.

It is desirable to make the color conversion layer 183 as thick as possible to increase the color conversion efficiency for both the color filter 180 formed by inkjet printing and the film-type color filter 180a. On the other hand, when the color conversion layer 183 is too thick, the light emitted by the color conversion approximates Lambertian, but the blue light that is not color-converted has an emission angle limited by the light-shielding part 181. Therefore, a problem undesirably occurs in that the display color of the display image has viewing angle dependence. To match the light distribution of the light of the subpixels in which the color conversion layer 183 is provided with the light distribution of the blue light that is not color-converted, it is desirable to set the thickness of the color conversion layer 183 to be about half of the opening size of the light-shielding part 181.

For example, in the case of a high-definition image display device of about 250 ppi (pitch per inch), the pitch of the subpixels 20 is about 30 μm, and so it is desirable for the thickness of the color conversion layer 183 to be about 15 μm. Here, when the color conversion material is made of spherical fluorescer particles, it is favorable to stack in a close-packed structure to suppress light leakage from the light-emitting element 150. It is therefore necessary to use at least three layers of particles. Accordingly, it is favorable for the particle size of the fluorescer material included in the color conversion layer 183 to be, for example, not more than about 5 μm, and more favorably not more than about 3 μm.

After the color filters 180 and 180a are formed, the structure body 1192 shown in FIG. 10A, etc., is diced together with the color filters 180 and 180a to form the image display device. The formation process of the color filters 180 and 180a may be performed after dicing the structure body 1192.

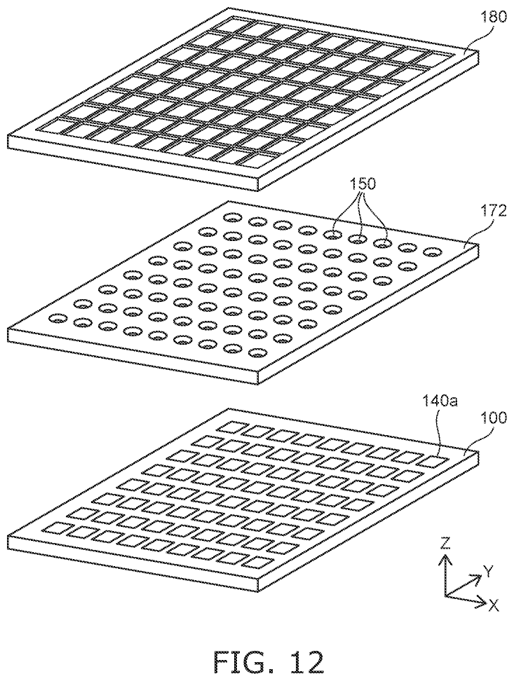

FIG. 12 is a schematic perspective view illustrating the image display device according to the embodiment.

In the image display device of the embodiment as shown in FIG. 12, the light-emitting circuit part 172 that includes many light-emitting elements 150 is located on the circuit board 100. The graphene layer 140 shown in FIG. 1 includes the graphene sheet 140a. The graphene sheets 140a are located on the circuit board 100 for each of the light-emitting elements 150. The color filter 180 is located on the light-emitting circuit part 172. The other embodiments and modifications described below also have configurations similar to the configuration shown in FIG. 12.

Effects of the image display device 1 of the embodiment will now be described.

According to the method for manufacturing the image display device 1 of the embodiment, the light-emitting element 150 is formed by performing crystal growth of the semiconductor layer 1150 on the wafer 1100 and by etching the semiconductor layer 1150. The circuit 101 that includes the transistor 103 driving the light-emitting element 150, etc., is pre-made in the wafer 1100. Therefore, the manufacturing processes are markedly reduced compared to when the singulated light-emitting elements are individually transferred.

According to the method for manufacturing the image display device 1 of the embodiment, the graphene layer 1140 can be formed on the planarized surface 112F of the wafer 1100, and can be used as the seed for performing crystal growth of the semiconductor layer 1150.

For example, in an image display device having 4K image quality, the number of subpixels is greater than 24 million, and in the case of an image display device having 8K image quality, the number of subpixels is greater than 99 million. When individually forming and mounting such a large quantity of light-emitting elements to a circuit board, an enormous amount of time is necessary. It is therefore difficult to realize an image display device that uses micro LEDs at a realistic cost. Also, when individually mounting a large quantity of light-emitting elements, the yield decreases due to connection defects when mounting, etc., and an even higher cost is unavoidable.

In contrast, according to the method for manufacturing the image display device 1 of the embodiment, the transfer process of the light-emitting elements 150 can be reduced because the light-emitting elements 150 are formed after forming the entire semiconductor layer 1150 on the graphene layer 1140 formed on the wafer 1100. Therefore, according to the method for manufacturing the image display device 1 of the embodiment, compared to a conventional manufacturing method, the time of the transfer process can be reduced, and the number of processes can be reduced.

Because the semiconductor layer 1150 that has a uniform crystal structure is grown on the graphene layer 1140, the light-emitting element 150 can be self-aligningly provided by appropriately patterning the graphene layer 1140. This is favorable for a higher-definition display because alignment of the light-emitting elements 150 on the wafer 1100 is unnecessary, and it is easy to downsize the light-emitting element 150.

After the light-emitting element 150 is formed directly on the wafer 1100 by etching, etc., the light-emitting element 150 and the circuit element formed inside the wafer 1100 of the light-emitting element 150 are electrically connected by via formation; therefore, a uniform connection structure can be realized, and the reduction of the yield can be suppressed.

According to the embodiment, low-temperature sputtering technology can be used in the process of forming the semiconductor layer 1150 on the wafer 1100 in which the circuit 101 is made. Such film formation technology can be performed in a low-temperature environment of about 500° C.; therefore, the damage to the wafer 1100, the circuit element inside the wafer 1100, etc., can be minimized, and the yield of the product can be increased.

According to the embodiment, the light-emitting element 150 is formed in a higher layer than the transistor 103, etc. The light-emitting element 150 that is formed in a different layer and the circuit 101 including the transistor 103, etc., are connected to each other by the via 161d formed to extend through the second and first inter-layer insulating films 156 and 112. Thus, a uniform connection structure can be easily realized using technically-established multilevel wiring technology, and the yield can be increased. Accordingly, the reduction of the yield due to connection defects of the light-emitting elements, etc., is suppressed.

### Second Embodiment

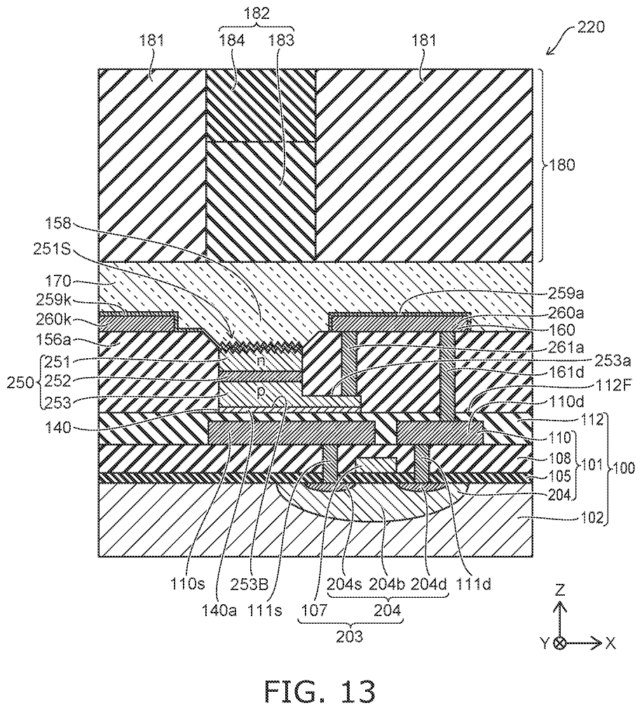

FIG. 13 is a schematic cross-sectional view illustrating a portion of an image display device according to the embodiment.

The embodiment differs from the other embodiment described above in that an n-type semiconductor layer 251 provides a light-emitting surface 251S, and the configuration of a transistor 203 is different. The same components as those of the other embodiment are marked with the same reference numerals, and a detailed description is omitted as appropriate.

As shown in FIG. 13, a subpixel 220 of the image display device of the embodiment includes the transistor 203, the first wiring layer 110, the first inter-layer insulating film 112, the graphene layer 140, a light-emitting element 250, the second inter-layer insulating film 156a, the second wiring layer 160, and the via (the first via) 161d.

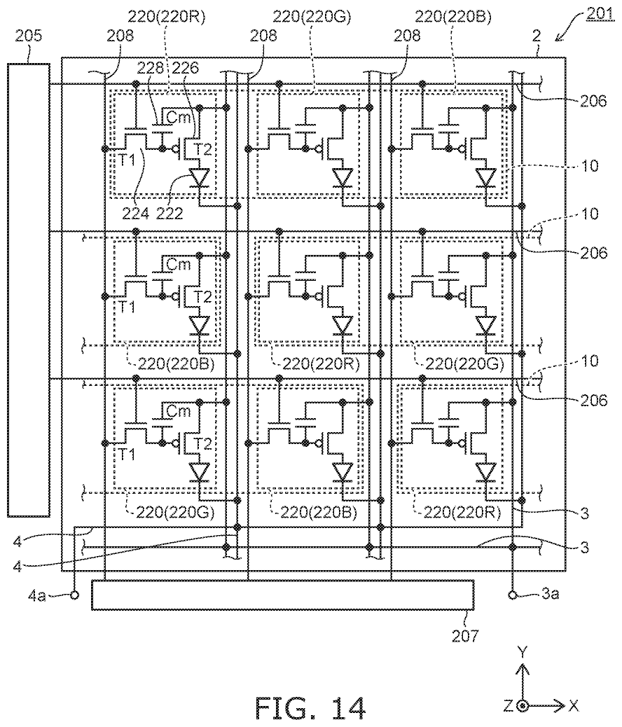

The transistor 203 is formed in the substrate 102. In addition to the transistor 203 for driving the light-emitting element 250, other circuit elements such as transistors, capacitors, etc., are formed in the substrate 102, and the circuit 101 is configured using wiring parts, etc. For example, the transistor 203 corresponds to a drive transistor 226 shown in FIG. 14 below, and the drive transistor 226, a select transistor 224, a capacitor 228, etc., are circuit elements. In the following description, the circuit 101 includes an element formation region 204 in which circuit elements are formed, the insulating layer 105, the first wiring layer 110, the vias 111d and 111s, and the insulating film 108. The substrate 102, the insulating layer 105, the first wiring layer 110, the vias 111d and 111s, and the insulating film 108 have the same functions as those of the other embodiment described above, and are formed of the same materials. Similarly to the other embodiment described above, other components such as the substrate 102, the circuit 101, the first inter-layer insulating film 112, etc., are referred to as being included in the circuit board 100.

The transistor 203 includes an n-type semiconductor region 204b, p-type semiconductor regions 204s and 204d, and the gate 107. The gate 107 is located on the n-type semiconductor region 204b with the insulating layer 105 interposed. The insulating layer 105 is provided to insulate the element formation region 204 and the gate 107 and to sufficiently isolate from the other adjacent circuit elements. A channel may be formed in the n-type semiconductor region 204b when a voltage is applied to the gate 107. The transistor 203 is a p-channel transistor, e.g., a p-channel MOSFET.

The element formation region 204 is located in the substrate 102. The element formation region 204 is formed from the surface of the substrate 102 in the depth direction of the substrate 102, i.e., the negative direction of the Z-axis. The element formation region 204 includes the n-type semiconductor region 204b and the p-type semiconductor regions 204s and 204d. The p-type semiconductor regions 204s and 204d are provided to be separated from each other at the surface vicinity of the element formation region 204. The n-type semiconductor region 204b is formed to surround the peripheries of the p-type semiconductor regions 204s and 204d and is located also between the p-type semiconductor regions 204s and 204d when projected onto the XY plane. The n-type semiconductor region 204b also is formed below each of the p-type semiconductor regions 204s and 204d.

In the transistor 203, a channel is formed in the n-type semiconductor region 204b when a voltage lower than that of the p-type semiconductor region 204s is applied to the gate 107. The current that flows between the p-type semiconductor regions 204s and 204d is controlled by the voltage of the gate 107 with respect to the p-type semiconductor region 204s.

The graphene layer 140 is located on the planarized surface 112F. The graphene layer 140 includes the multiple graphene sheets 140a. The graphene sheet 140a are provided for each light-emitting element 250. The outer perimeter of the graphene sheet 140a substantially matches the outer perimeter of the light-emitting element 250 when projected onto the XY plane.

The light-emitting element 250 includes the light-emitting surface 251S. Similarly to the other embodiment described above, the light-emitting element 250 is a prismatic or cylindrical element including a bottom surface 253B on the graphene sheet 140a. In the light-emitting element 250, the light-emitting surface 251S is the surface at the side opposite to the bottom surface 253B.

The light-emitting element 250 includes a p-type semiconductor layer 253, a light-emitting layer 252, and the n-type semiconductor layer 251. The p-type semiconductor layer 253, the light-emitting layer 252, and the n-type semiconductor layer 251 are stacked in this order from the bottom surface 253B toward the light-emitting surface 251S. According to the embodiment, the light-emitting surface 251S is provided by the n-type semiconductor layer 251. Although the light-emitting surface 251S is roughened in the example, the light-emitting surface 251S may not be roughened as in the modifications of the other embodiment described above.

The p-type semiconductor layer 253 includes a connection part 253a. For example, the connection part 253a is provided to protrude in one direction together with the graphene sheet 140a over the planarized surface 112F from the p-type semiconductor layer 253. The protrusion direction is not limited to one direction and may be two or more directions, or the protrusion may be provided over the entire perimeter of the p-type semiconductor layer 253. The height of the connection part 253a is the same as the height of the p-type semiconductor layer 253, or the side surface of the light-emitting element 250 is formed in a staircase shape by setting the height of the connection part 253a to be less than the height of the p-type semiconductor layer 253. The connection part 253a is of the p-type and is electrically connected with the p-type semiconductor layer 253. In the example, the connection part 253a is provided to electrically connect a via 261a to the p-type semiconductor layer 253.

The light-emitting element 250 has a shape similar to the light-emitting element 150 shown in FIG. 1 when projected onto the XY plane. In the light-emitting element 250, an appropriate shape is selected according to the layout of the circuit elements, etc.

The light-emitting element 250 is a light-emitting diode similar to the light-emitting element 150 of the other embodiment described above. Specifically, the wavelength of the light emitted by the light-emitting element 250 is, for example, a blue light emission of about 467 nm±30 nm or a bluish-violet light emission of about 410 nm±30 nm. The wavelength of the light emitted by the light-emitting element 250 is not limited to these values and can be an appropriate value.

The second inter-layer insulating film 156a is provided to cover the planarized surface 112F, the graphene layer 140 including the graphene sheet 140a, and the light-emitting element 250. The second inter-layer insulating film 156a is formed of a light-reflective material and is favorably a white resin. A configuration example of the white resin is similar to those of the modifications shown in FIGS. 2A and 2B.

The second wiring layer 160 is located on the second inter-layer insulating film 156a. The second wiring layer 160 includes wiring parts 260a and 260k. In the example, a portion of the wiring part 260a is located above the connection part 253a. In the example, the wiring part 260k is located at a position separated from the opening 158.

The via (the first via) 161d extends through the second and first inter-layer insulating films 156a and 112 and reach the wiring part 110d. The via 161d is located between the wiring part 260a and the wiring part 110d and electrically connects the wiring part 260a and the wiring part 110d.

The via (the second via) 261a extends through the second inter-layer insulating film 156a and reach the connection part 253a. The via 261a is located between the wiring part 260a and the connection part 253a and electrically connects the wiring part 260a and the connection part 253a.

A light-transmitting electrode 259k is formed over the wiring part 260k. The light-transmitting electrode 259k is formed over the light-emitting surface 251S. The light-transmitting electrode 259k is located between the wiring part 260k and the light-emitting surface 251S and electrically connects the wiring part 260k and the light-emitting surface 251S. For example, the light-transmitting electrode 259k and the wiring part 260k are connected to the ground line 4 of the circuit shown in FIG. 14.

A light-transmitting electrode 259a is formed over the wiring part 260a.

The p-type semiconductor layer 253 is electrically connected to the wiring part 110d via the connection part 253a, the via 261a, the wiring part 260a, and the via 161d. The wiring part 110d is electrically connected to the p-type semiconductor region 204d, i.e., the drain electrode of the transistor 203, by the via 111d.

For example, the n-type semiconductor layer 251 is electrically connected to the ground line 4 of the circuit shown in FIG. 14 via the light-transmitting electrode 259k and the wiring part 260k.

Similarly to the modification shown in FIG. 2A, a direct connection to the light-emitting surface 251S may be performed by a wiring part of the second wiring layer 160 instead of the light-transmitting electrode. As in the first embodiment, the second inter-layer insulating film 156 that is formed of a light-transmitting material may be used instead of the second inter-layer insulating film 156a.

In the subpixel 220, the surface resin layer 170 is located on the second inter-layer insulating film 156a, the second wiring layer 160, and the light-transmitting electrodes 259k and 259a, and the color filter 180 is located on the surface resin layer 170.

FIG. 14 is a schematic block diagram illustrating the image display device according to the embodiment.

As shown in FIG. 14, the image display device 201 of the embodiment includes the display region 2, a row selection circuit 205, and a signal voltage output circuit 207. In the display region 2, similarly to the other embodiment described above, for example, the subpixels 220 are arranged in a lattice shape in the XY plane.

Similarly to the other embodiment described above, the pixel 10 includes multiple subpixels 220 that emit light of different colors. A subpixel 220R emits red light. A subpixel 220G emits green light. A subpixel 220B emits blue light. The light emission color and luminance of one pixel 10 are determined by the three types of the subpixels 220R, 220G, and 220B emitting light of the desired luminances.

One pixel 10 includes three subpixels 220R, 220G, and 220B, and, for example, the subpixels 220R, 220G, and 220B are arranged in a straight line along the X-axis as in the example. In the pixels 10, subpixels of the same color may be arranged in the same column, or subpixels of different colors may be arranged in each column as in the example.

The subpixel 220 includes a light-emitting element 222, the select transistor 224, the drive transistor 226, and the capacitor 228. In FIG. 14, the select transistor 224 may be displayed as T1, the drive transistor 226 may be displayed as T2, and the capacitor 228 may be displayed as Cm.

According to the embodiment, the light-emitting element 222 is located at the ground line 4 side, and the drive transistor 226 that is connected in series to the light-emitting element 222 is located at the power supply line 3 side. That is, the drive transistor 226 is connected to a higher potential side than the light-emitting element 222. The drive transistor 226 is a p-channel transistor.

The select transistor 224 is connected between a signal line 208 and the gate electrode of the drive transistor 226. The capacitor 228 is connected between the power supply line 3 and the gate electrode of the drive transistor 226.

To drive the drive transistor 226 that is a p-channel transistor, the signal voltage output circuit 207 supplies, to the signal line 208, a signal voltage that has a different polarity from that of the other embodiment described above.

According to the embodiment, because the polarity of the drive transistor 226 is a p-channel, the polarity of the signal voltage and the like are different from those of the other embodiment described above. Specifically, the row selection circuit 205 supplies a select signal to a scanning line 206 to sequentially select one row from the arrangement of the m rows of subpixels 220. The signal voltage output circuit 207 supplies a signal voltage having an analog voltage value necessary for the subpixels 220 of the selected row. The drive transistors 226 of the subpixels 220 of the selected row allow currents corresponding to the signal voltages to flow in the light-emitting elements 222. The light-emitting elements 222 emit light of luminances corresponding to the currents that flow.

A method for manufacturing the image display device of the embodiment will now be described.

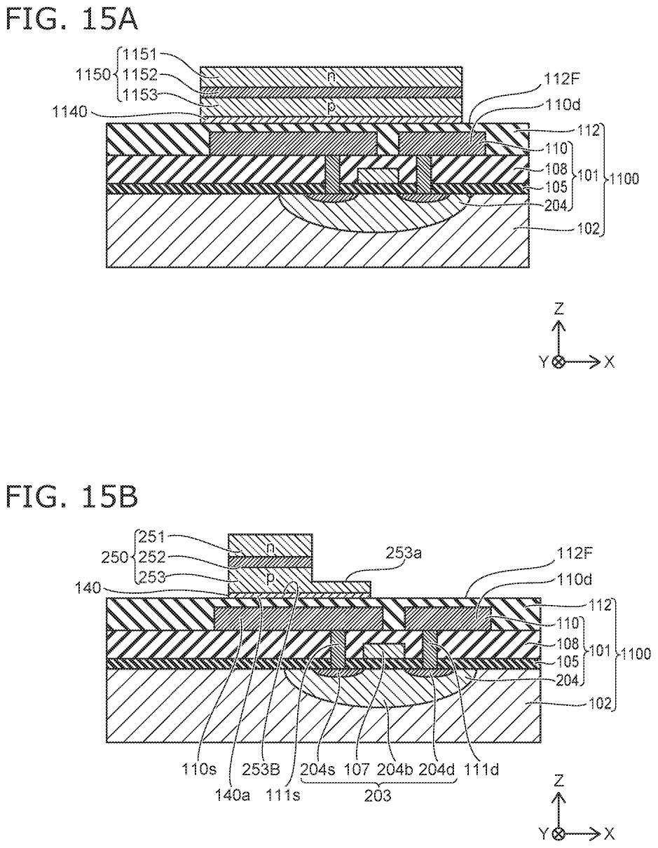

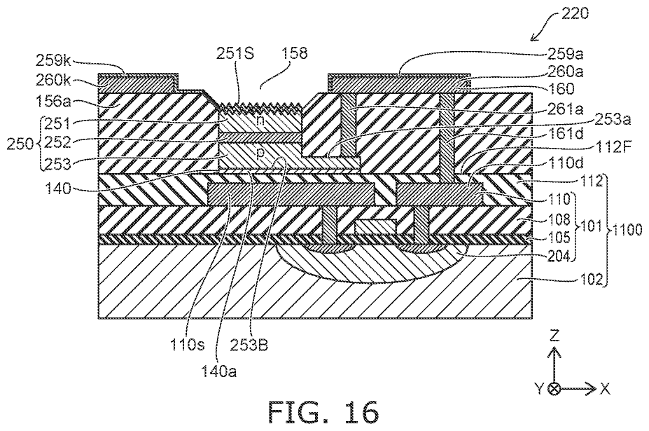

FIGS. 15A to 16 are schematic cross-sectional views illustrating the method for manufacturing the image display device of the embodiment.

The wafer 1100 of the other embodiment described above with reference to FIGS. 5A and 5B can be used in the example. However, according to the embodiment, the circuit 101 that is formed inside the wafer 1100 includes the element formation region 204 and the transistor 203. In the following description, the process of FIG. 15A and subsequent processes are applied after the process of FIG. 5B.

According to the method for manufacturing the image display device of the embodiment as shown in FIG. 15A, the semiconductor layer 1150 is formed on the graphene layer 1140 formed on the planarized surface 112F of the wafer 1100. The semiconductor layer 1150 includes the p-type semiconductor layer 1153, the light-emitting layer 1152, and the n-type semiconductor layer 1151 formed in this order from the graphene layer 1140 in the positive direction of the Z-axis. The semiconductor layer 1150 is formed using film formation technology similar to that of the other embodiment described above. In other words, to form the semiconductor layer 1150, physical vapor deposition such as vapor deposition, ion beam deposition, MBE, or the like is used, and it is favorable to use low-temperature sputtering.

Similarly to the other embodiment described above, there are cases where deposits that include materials of the growth species are deposited on the planarized surface 112F at which the graphene layer 1140 does not exist.

As shown in FIG. 15B, the semiconductor layer 1150 on the graphene layer 1140 shown in FIG. 15A is patterned into the desired shape by etching to form the light-emitting element 250. In the formation process of the light-emitting element 250, the connection part 253a is formed, and then the portion of the light-emitting element 250 other than the connection part 253a is formed. The graphene layer 1140 shown in FIG. 15A is over etched when forming the connection part 253a to form the graphene sheet 140a having an outer perimeter shape that substantially matches the outer perimeter shape of the bottom surface 253B of the light-emitting element 250. The outer perimeter of the bottom surface 253B includes the outer perimeters of the p-type semiconductor layer 253 and the connection part 253a.

As shown in FIG. 16, the second inter-layer insulating film 156a is formed to cover the planarized surface 112F, the graphene layer 140, and the light-emitting element 250.

The opening 158 is formed by removing a portion of the second inter-layer insulating film 156a to expose the light-emitting surface 251S from under the second inter-layer insulating film 156a. Similarly to the other embodiment described above, it is favorable to roughen the light-emitting surface 251S.

The via 161d is formed to extend through the second and first inter-layer insulating films 156a and 112 and reach the wiring part 110d. The via 261a is formed to extend through the second inter-layer insulating film 156a and reach the connection part 253a.

The second wiring layer 160 that includes the wiring parts 260a and 260k is formed on the second inter-layer insulating film 156a. The wiring part 260a is connected to the vias 161d and 261a.

The light-transmitting electrode 259k is formed over the light-emitting surface 251S and formed over the wiring part 260k. Simultaneously, the light-transmitting electrode 259k is formed also between the light-emitting surface 251S and the wiring part 260k to electrically connect the light-emitting surface 251S and the wiring part 260k. The light-transmitting electrode 259a is formed over the wiring part 260a.

Thereafter, the subpixel 220 of the image display device of the embodiment is formed by providing the color filter 180 shown in FIG. 13, etc.

Effects of the image display device of the embodiment will now be described.

In the image display device of the embodiment has effects similar to those of the other embodiment described above. Specifically, in the image display device of the embodiment, the manufacturing processes can be markedly reduced compared to when singulated light-emitting elements are individually transferred.

In the image display device of the embodiment, the thickness of the n-type semiconductor layer 251 can be increased because the resistance value of the n-type semiconductor layer 251 can be lower than that of the p-type semiconductor layer 253. It is therefore easier to roughen the light-emitting surface 251S. The circuit that drives the light-emitting element 250 having the n-type semiconductor layer 251 as the light-emitting surface 251S can be configured by setting the polarity of the transistor 203 to be a p-channel. Accordingly, the image display device of the embodiment is advantageous in that the degree of freedom of the circuit element arrangement and circuit design is increased, etc.

### Third Embodiment

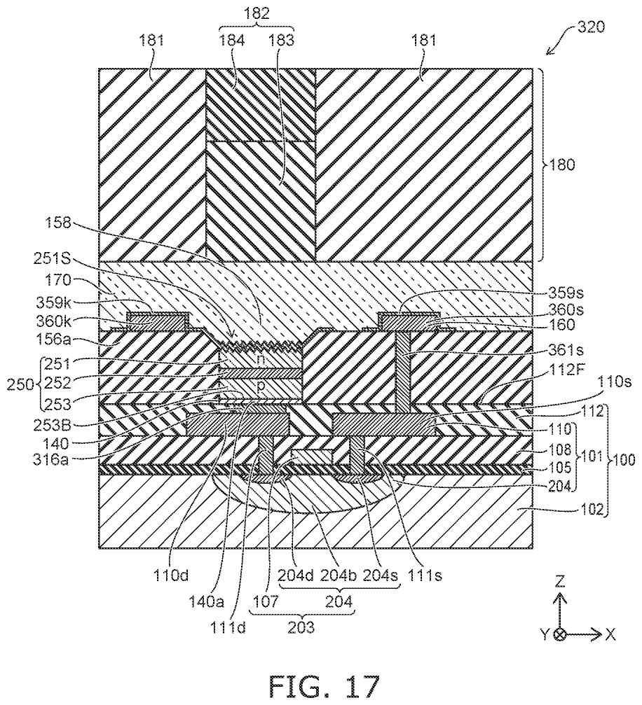

FIG. 17 is a schematic cross-sectional view illustrating a portion of an image display device according to the embodiment.

The image display device of the embodiment differs from that of the other embodiments described above in that the first wiring layer 110 and the light-emitting element 250 are connected by a plug 316a. In the example, the light-emitting element 250 in which the light-emitting surface 251S is the n-type semiconductor layer 251 is driven by the p-channel transistor 203. The same components as those of the other embodiments described above are marked with the same reference numerals, and a detailed description is omitted as appropriate.

As shown in FIG. 17, the image display device of the embodiment includes a subpixel 320. The subpixel 320 includes the transistor 203, the first wiring layer 110, the first inter-layer insulating film 112, the plug 316a, the graphene layer 140, the light-emitting element 250, the second inter-layer insulating film 156a, a via 361s, and the second wiring layer 160.

The plug 316a is located between the wiring part (a first wiring part) 110d and the graphene sheet 140a. The light-emitting element 250 is located on the graphene sheet 140a. Here, the graphene sheet 140a and the graphene layer 140 are thin enough that the values of the conductivities in the thickness direction of the graphene layer 140 and the graphene sheet 140a allow enough current to flow that the light-emitting element 250 can emit light with the desired brightness. Accordingly, the light-emitting element 250 is electrically connected with a sufficiently low resistance value to the wiring part 110d via the graphene sheet 140a.

The side surface of the plug 316a is covered with the first inter-layer insulating film 112. The surface at which the plug 316a contacts the graphene sheet 140a is in substantially the same plane as the planarized surface 112F. That is, the plug 316a is provided to be embedded in the first inter-layer insulating film 112 and is connected to the graphene sheet 140a in substantially the same plane as the planarized surface 112F.

The p-type semiconductor layer 253 of the light-emitting element 250 is connected to the graphene sheet 140a at the bottom surface 253B. Accordingly, the p-type semiconductor layer 253 is electrically connected to the p-type semiconductor region 204d corresponding to the drain electrode of the transistor 203 via the graphene sheet 140a, the plug 316a, the wiring part 110d, and the via 111d.

The second inter-layer insulating film 156a is provided to cover the planarized surface 112F, the graphene layer 140 including the graphene sheet 140a, and the light-emitting element 250.

The second wiring layer 160 that is located on the second inter-layer insulating film 156a includes wiring parts 360k and 360s. For example, the wiring part 360k is connected to the ground line 4 of the circuit of FIG. 14. For example, the wiring part 360s is connected to the power supply line 3 of the circuit of FIG. 14.

The via (the first via) 361s extends through the second and first inter-layer insulating films 156a and 112 and reach the wiring part (a second wiring part) 110s. The via 361s is located between the wiring part 360s and the wiring part 110s and electrically connects the wiring part 360s and the wiring part 110s.

The light-emitting surface 251S is formed by removing a portion of the second inter-layer insulating film 156a. The light-emitting surface 251S is exposed from under the second inter-layer insulating film 156a via the opening 158. A light-transmitting electrode 359k is provided over the light-emitting surface 251S. The light-transmitting electrode 359k is provided over the wiring part 360k and between the light-emitting surface 251S and the wiring part 360k. The light-transmitting electrode 359k electrically connects the light-emitting surface 251S and the wiring part 360k.

A light-transmitting electrode 359s is provided over the wiring part 360s. For example, the light-transmitting electrode 359s and the wiring part 360s are connected to the power supply line 3 of the circuit of FIG. 14.

Instead of using the light-transmitting electrode 359k, one end of the wiring part may be connected directly to the light-emitting surface 251S. Light-transmitting conductive films that include the light-transmitting electrodes 359k and 359s may be used instead of the second wiring layer 160, and the connections to the ground line 4 and the power supply line 3 of the circuit of FIG. 14 may be performed respectively by the light-transmitting electrodes 359k and 359s.

A method for manufacturing the image display device of the embodiment will now be described.

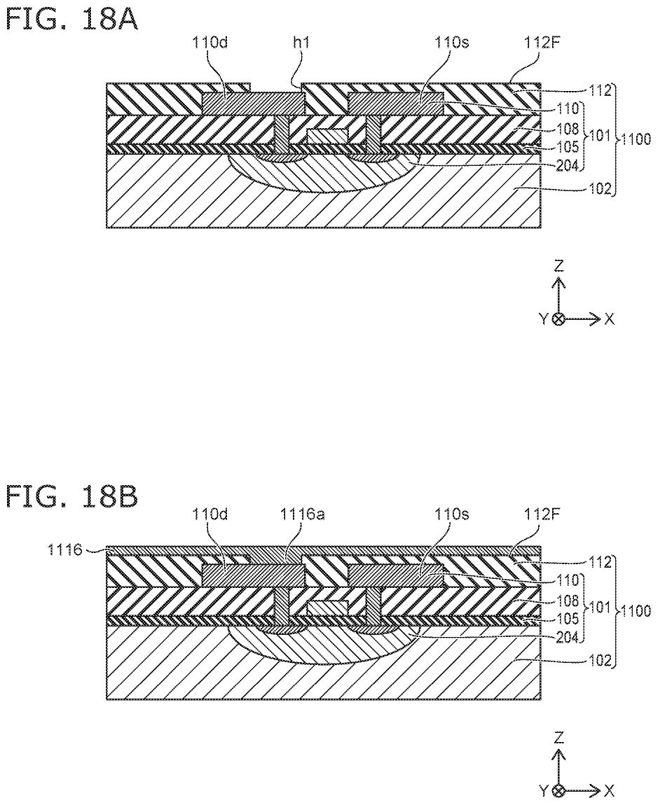

FIGS. 18A to 20B are schematic cross-sectional views illustrating the method for manufacturing the image display device of the embodiment.

The wafer 1100 of the other embodiment described above with reference to FIG. 5A is used in the example. However, the circuit 101 that is formed inside the wafer 1100 include the element formation region 204 and the transistor 203. In the following description, the process of FIG. 18A and subsequent processes are applied after the process of FIG. 5A.

As shown in FIG. 18A, a contact hole hl is formed in the first inter-layer insulating film 112 of the prepared wafer 1100. The contact hole hl is formed at the position at which the wiring part 110d will be located when projected onto the XY plane. The contact hole hl is formed to reach the wiring part 110d. The contact hole hl may be formed to be deeper than the surface of the wiring part 110d in the thickness direction of the wiring part 110d.

As shown in FIG. 18B, a metal layer 1116 is formed over the planarized surface 112F of the first inter-layer insulating film 112, the contact hole hi, and the wiring part 110d exposed from under the first inter-layer insulating film 112 via the contact hole hl.

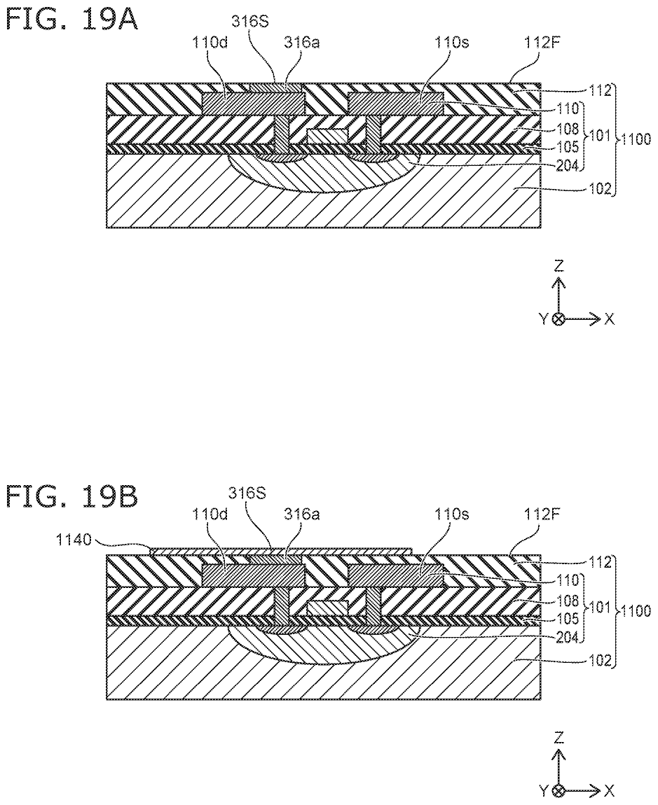

As shown in FIG. 19A, the metal layer 1116 shown in FIG. 18B is polished by, for example, chemical mechanical polishing (CMP), etc., until the planarized surface 112F is exposed from under the metal layer 1116. Although it is unnecessary to match the initial planarized surface 112F shown in FIG. 18A, the initial planarized surface 112F is exposed in the following description.

In FIG. 19A, a surface 316S of the plug 316a exposed from under the metal layer 1116 by polishing is in substantially the same plane as the planarized surface 112F without protruding in the positive direction of the Z-axis with respect to the planarized surface 112F and without forming a recess in the negative direction of the Z-axis.

As shown in FIG. 19B, the graphene layer 1140 is formed over the planarized surface 112F and the surface 316S of the plug 316a. At this time, the graphene layer 1140 is electrically connected with the plug 316a.

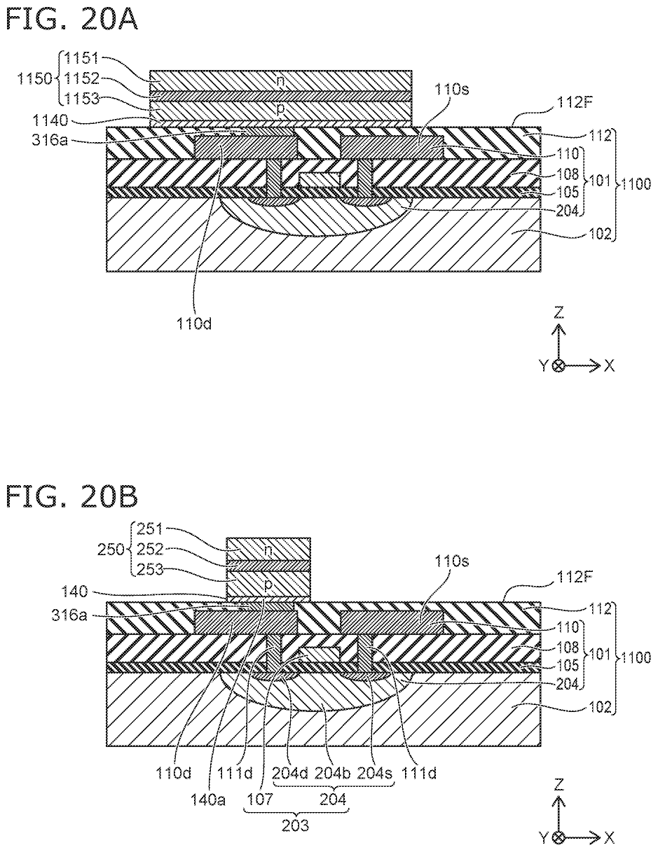

As shown in FIG. 20A, the semiconductor layer 1150 is formed on the graphene layer 1140. In the example, the semiconductor layer 1150 includes the p-type semiconductor layer 1153, the light-emitting layer 1152, and the n-type semiconductor layer 1151 formed in this order from the graphene layer 1140 side.

As shown in FIG. 20B, the semiconductor layer 1150 shown in FIG. 20A is patterned by etching to form the light-emitting element 250 in the desired shape. The graphene layer 1140 shown in FIG. 20A is over etched when forming the light-emitting element 250 to form the graphene sheet 140a having an outer perimeter that substantially matches the outer perimeter of the light-emitting element 250.

Thereafter, similarly to the other embodiments, the second inter-layer insulating film 156a, the opening 158, the via 361s, the second wiring layer 160, the light-transmitting electrodes 359k and 359s, and the color filter 180 shown in FIG. 17 are formed, and the subpixel 320 is formed.

Effects of the image display device of the embodiment will now be described.

The image display device of the embodiment has effects similar to those of the other embodiments described above. Specifically, in the image display device of the embodiment, the manufacturing processes can be markedly reduced compared to when singulated light-emitting elements are individually transferred. In the image display device of the embodiment, the electrical connection to the circuit elements such as transistor 203 and the like formed in the layers lower than the light-emitting element 250 is performed by the plug 316a instead of a via. Accordingly, the structure of the subpixel 320 can be simpler; the manufacturing processes can be simpler, and a yield increase can be expected.

### Fourth Embodiment

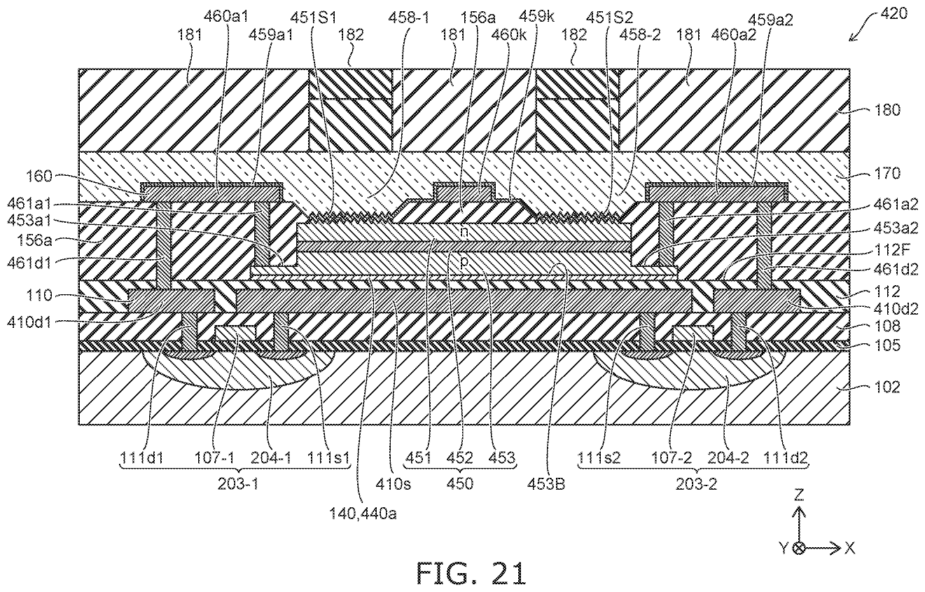

FIG. 21 is a schematic cross-sectional view illustrating a portion of an image display device according to the embodiment.

According to the embodiment, an image display device having a higher luminous efficiency is realized by forming multiple light-emitting surfaces 451S1 and 451S2 in a single semiconductor layer 450 including a light-emitting layer 452. In the following description, the same components as those of the other embodiments described above are marked with the same reference numerals, and a detailed description is omitted as appropriate.

As shown in FIG. 21, the image display device of the embodiment includes a subpixel group 420. The subpixel group 420 includes transistors (multiple transistors) 203-1 and 203-2, the first wiring layer 110, the first inter-layer insulating film 112, the graphene layer 140, the semiconductor layer 450, the second inter-layer insulating film 156a, the second wiring layer 160, and vias 461d1 and 461d2.

The graphene layer 140 includes a graphene sheet (a third part) 440a. The semiconductor layer 450 is located on the graphene sheet 440a. Similarly to the other embodiments described above, the graphene layer 140 includes the multiple graphene sheets 440a, and the semiconductor layer 450 is provided for each graphene sheet 440a. To avoid complexity of illustration in the cross-sectional views of the embodiment and modifications described below, the reference numeral of the graphene layer 140 is labeled next to the reference numeral of the graphene sheet 440a.

According to the embodiment, by switching the p-channel transistors 203-1 and 203-2 on, electrons are injected through one side of the semiconductor layer 450, and holes are injected through the other side of the semiconductor layer 450. The holes and the electrons are injected into the semiconductor layer 450, and the light-emitting layer 452 emits light due to the combination of the holes and electrons.

For example, the circuit configuration shown in FIG. 14 is applied to the drive circuit for driving the light-emitting layer 452. A configuration also can be used in which the semiconductor layer is driven by an n-channel transistor by vertically interchanging the p-type semiconductor layer and n-type semiconductor layer of the semiconductor layer. In such a case, for example, the circuit configuration of FIG. 3 is applied to the drive circuit.

The configuration of the subpixel group 420 will now be described in detail.

The transistors 203-1 and 203-2 are formed in the substrate 102. The transistor 203-1 includes an element formation region 204-1, a gate 107-1, and vias 111s1 and 111d1. The transistor 203-2 includes an element formation region 204-2, a gate 107-2, and vias 111s2 and 111d2.

In the example, the element formation regions 204-1 and 204-2 are n-type semiconductor regions. The element formation regions 204-1 and 204-2 are formed to be separated from each other in the X-axis direction inside the substrate 102. The n-type semiconductor regions of the element formation regions 204-1 and 204-2 each include channel regions. Two p-type semiconductor regions are formed to be separated from each other in the element formation region 204-1. The two p-type semiconductor regions that are formed inside the element formation region 204-1 include the source region and drain region of the transistor 203-1. Two p-type semiconductor regions are formed to be separated from each other in the element formation region 204-2. The two p-type semiconductor regions that are formed inside the element formation region 204-2 include the source region and drain region of the transistor 203-2.

The insulating layer 105 is located on the element formation regions 204-1 and 204-2 and the substrate 102, and the gates 107-1 and 107-2 are located respectively on the element formation regions 204-1 and 204-2 with the insulating layer 105 interposed. The transistors 203-1 and 203-2 are p-channel MOSFETs. The transistors 203-1 and 203-2 have configurations similar to the transistor 203 according to the second and third embodiments described above, and a detailed description is therefore omitted.

The insulating film 108 is located on the insulating layer 105 and the gates 107-1 and 107-2. The first wiring layer 110 is located on the insulating film 108.

The vias 111s1 and 111d1 are located respectively between the first wiring layer 110 and the two p-type semiconductor regions of the transistor 203-1. The vias 111s2 and 111d2 are located respectively between the first wiring layer 110 and the two p-type semiconductor regions of the transistor 203-2.

The first wiring layer 110 includes wiring parts 410s, 410d1, and 410d2. The via 111s1 is located between the wiring part 410s and the p-type semiconductor region corresponding to the source region of the transistor 203-1 and electrically connects the p-type semiconductor region and the wiring part 410s. The via 111s2 is located between the wiring part 410s and the p-type semiconductor region corresponding to the source region of the transistor 203-2 and electrically connects the p-type semiconductor region and the wiring part 410s. For example, the wiring part 410s is connected to the power supply line 3 of the circuit of FIG. 14.

The via 111d1 is located between the wiring part 410d1 and the p-type semiconductor region corresponding to the drain region of the transistor 203-1 and electrically connects the p-type semiconductor region and the wiring part 410d1. The via 111d2 is located between the wiring part 410d2 and the p-type semiconductor region corresponding to the drain region of the transistor 203-2 and electrically connects the p-type semiconductor region and the wiring part 410d2.

The first inter-layer insulating film (the first insulating film) 112 covers the insulating film 108 and the first wiring layer 110. The graphene layer 140 including the graphene sheet 140a is located on the planarized surface 112F of the first inter-layer insulating film 112.

The semiconductor layer 450 is located on the graphene sheet 140a. The semiconductor layer 450 includes the surface including the light-emitting surfaces 451S1 and 451S2, and a bottom surface 453B at the side opposite to the surface including the light-emitting surfaces 451S1 and 451S2. The single semiconductor layer 450 is located between the two drive transistors 203-1 and 203-2 arranged along the X-axis direction.

The semiconductor layer 450 includes a p-type semiconductor layer 453, the light-emitting layer 452, and an n-type semiconductor layer 451. The semiconductor layer 450 includes the p-type semiconductor layer 453, the light-emitting layer 452, and the n-type semiconductor layer 451 stacked in this order from the planarized surface 112F toward the light-emitting surfaces 451S1 and 451S2. The bottom surface 453B is a surface of the p-type semiconductor layer 453. The light-emitting surfaces 451S1 and 451S2 are surfaces at the side opposite to the bottom surface 453B.

The p-type semiconductor layer 453 includes connection parts 453a1 and 453a2. The connection part 453a1 is provided to protrude in one direction together with the graphene sheet 440a from the p-type semiconductor layer 453 over the planarized surface 112F. The connection part 453a2 is provided to protrude together with the graphene sheet 440a over the planarized surface 112F from the p-type semiconductor layer 453 in a different direction from the connection part 453a1. The connection parts 453a1 and 453a2 are not limited to protrusions in one direction each, and may be provided to protrude in multiple directions each. Portions of a part protruding around the outer perimeter of the semiconductor layer 450 may be used as the connection parts 453a1 and 453a2. The side surface of the semiconductor layer 450 is formed in a staircase shape by setting the heights of the connection parts 453a1 and 453a2 to be less than the height of the semiconductor layer 450, and the heights of the connection parts 453a1 and 453a2 are the same as the height of the p-type semiconductor layer 453 or less than the height of the p-type semiconductor layer 453 as in the example.

The connection part 453a1 is of the p-type, and a via 461a1 of which one end is connected to the connection part 453a1 is electrically connected to the p-type semiconductor layer 453. The connection part 453a2 is of the p-type, and a via 461a2 of which one end is connected to the connection part 453a2 is electrically connected to the p-type semiconductor layer 453.

It is favorable for the wiring part 410s to function as a light-shielding plate. When projected onto the XY plane, the outer perimeter of the wiring part 410s is set to include the outer perimeter of the semiconductor layer 450 when the semiconductor layer 450 is projected onto the wiring part 410s. That is, the outer perimeter of the semiconductor layer 450 is set to be within the outer perimeter of the wiring part 410s when projected onto the XY plane. By such a setting, the wiring part 410s can shield the light scattered downward from the semiconductor layer 450 and can prevent malfunction of the circuit elements including the transistors 203-1 and 203-2 due to the irradiation of light.

The second inter-layer insulating film (the second insulating film) 156a covers the planarized surface 112F, the graphene layer 140 including the graphene sheet 440a, and the semiconductor layer 450. The light-emitting surface 451S1 is exposed from under the second inter-layer insulating film 156a via an opening 458-1. The light-emitting surface 451S2 is exposed from under the second inter-layer insulating film 156a via an opening 458-2. The second inter-layer insulating film 156a is formed of a light-reflective material, and is favorably formed of a white resin.

The via 461d1 extends through the second and first inter-layer insulating films 156a and 112 and reach the wiring part 410d1. The via 461d2 extends through the second and first inter-layer insulating films 156a and 112 and reach the wiring part 410d2.

The via 461a1 extends through the second inter-layer insulating film 156a and reach the connection part 453a1. The via 461a2 extends through the second inter-layer insulating film 156a and reach the connection part 453a2.

The second wiring layer 160 is located on the second inter-layer insulating film 156a. The second wiring layer 160 includes wiring parts 460a1, 460a2, and 460k. A portion of the wiring part 460a1 is located above the connection part 453a1. A portion of the wiring part 460a2 is located above the connection part 453a2. The wiring part 460k is located between the light-emitting surface 451S1 and the light-emitting surface 451S2. For example, the wiring part 460k is connected to the ground line 4 of FIG. 14.

The via 461d1 is located between the wiring part 460a1 and the wiring part 410d1 and electrically connects the wiring part 460a1 and the wiring part 410d1. The via 461d2 is located between the wiring part 460a2 and the wiring part 410d2 and electrically connects the wiring part 460a2 and the wiring part 410d2.

The via 461a1 is located between the wiring part 460a1 and the connection part 453a1 and electrically connects the wiring part 460a1 and the connection part 453a1. The via 461a2 is located between the wiring part 460a2 and the connection part 453a2 and electrically connects the wiring part 460a2 and the connection part 453a2.

Thus, the connection part 453a1 is connected to the wiring part 410d1 by the via 461a1, the wiring part 460a1, and the via 461d1. The connection part 453a2 is connected to the wiring part 410d2 by the via 461a2, the wiring part 460a2, and the via 461d2.

A light-transmitting electrode 459a1 is provided over the wiring part 460a1. A light-transmitting electrode 459a2 is provided over the wiring part 460a2. A light-transmitting electrode 459k is provided over the wiring part 460k. The light-transmitting electrode 459k is provided over the light-emitting surface 451S1. The light-transmitting electrode 459k also is located between the wiring part 460k and the light-emitting surface 451S1 and electrically connects the wiring part 460k and the light-emitting surface 451S1. The light-transmitting electrode 459k is provided over the light-emitting surface 451S2. The light-transmitting electrode 459k also is located between the wiring part 460k and the light-emitting surface 451S2 and electrically connects the wiring part 460k and the light-emitting surface 451S2.

The openings 458-1 and 458-2 are formed at positions corresponding respectively to the light-emitting surfaces 451S1 and 451S2 when projected onto the XY plane. The light-emitting surfaces 451S1 and 451S2 are formed at positions separated from each other on the n-type semiconductor layer 451. The light-emitting surface 451S1 is located at a position more proximate to the transistor 203-1. The light-emitting surface 45152 is located at a position more proximate to the transistor 203-2.

The openings 458-1 and 458-2 are, for example, square or rectangular when projected onto the XY plane. The openings 458-1 and 458-2 are not limited to quadrangular and may be circular, elliptical, polygonal such as hexagonal, etc. The light-emitting surfaces 451S1 and 451S2 also may be squares, rectangles, other polygons, circles, etc., when projected onto the XY plane. The shapes of the light-emitting surfaces 451S1 and 451S2 may be similar to or different from the shapes of the openings 458-1 and 458-2.

As described above, the light-transmitting electrode 459k is connected to the light-emitting surface 451S1 exposed from under the second inter-layer insulating film 156a via the opening 458-1. The light-transmitting electrode 459k also is connected to the light-emitting surface 451S2 exposed from under the second inter-layer insulating film 156a via the opening 458-2. Therefore, the electrons that are supplied from the light-transmitting electrode 459k are injected into the n-type semiconductor layer 451 from the light-emitting surfaces 451S1 and 451S2. On the other hand, holes are injected into the p-type semiconductor layer 453 via the connection parts 453a1 and 453a2.

The p-type semiconductor layer 453 is connected to the drain electrode of the transistor 203-1 via the connection part 453a1, the via 461a1, the wiring part 460a1, the via 461d1, the wiring part 410d1, and the via 111d1. For example, the source electrode of the transistor 203-1 is connected to the power supply line 3 of FIG. 14 by the via 111s1 and the wiring part 410s. Accordingly, holes are injected into the p-type semiconductor layer 453 by switching the transistor 203-1 on.

The p-type semiconductor layer 453 is connected to the drain electrode of the transistor 203-2 via the connection part 453a2, the via 461a2, the wiring part 460a2, the via 461d2, the wiring part 410d2, and the via 111d2. For example, the source electrode of the transistor 203-2 is connected to the power supply line 3 of FIG. 14 by the via 111s2 and the wiring part 410s. Accordingly, holes are injected into the p-type semiconductor layer 453 by switching the transistor 203-2 on.

The transistors 203-1 and 203-2 are drive transistors of adjacent subpixels and are sequentially driven. Accordingly, the holes that are injected from one of the two transistors 203-1 and 203-2 are injected into the light-emitting layer 452; the electrons that are injected through the light-emitting surfaces 451S1 and 451S2 are injected into the light-emitting layer 452, and the light-emitting layer 452 emits light.

According to the embodiment, the component of the drift current in a direction parallel to the XY plane is suppressed by the resistance of the n-type semiconductor layer 451 and the p-type semiconductor layer 453. Therefore, the electrons that are injected through the light-emitting surfaces 451S1 and 451S2 and the holes that are injected from the connection parts 453a1 and 453a2 both travel along the stacking direction of the semiconductor layer 450. Because a light emission source substantially does not operate further outward of the light-emitting surfaces 451S1 and 451S2, the multiple light-emitting surfaces 451S1 and 451S2 that are located in one semiconductor layer 450 can be selectively caused to emit light respectively by the transistors 203-1 and 203-2.

Thus, the light emission source of the semiconductor layer 450 is substantially determined by the arrangement of the light-emitting surfaces 451S1 and 451S2.

A method for manufacturing the image display device of the embodiment will now be described.

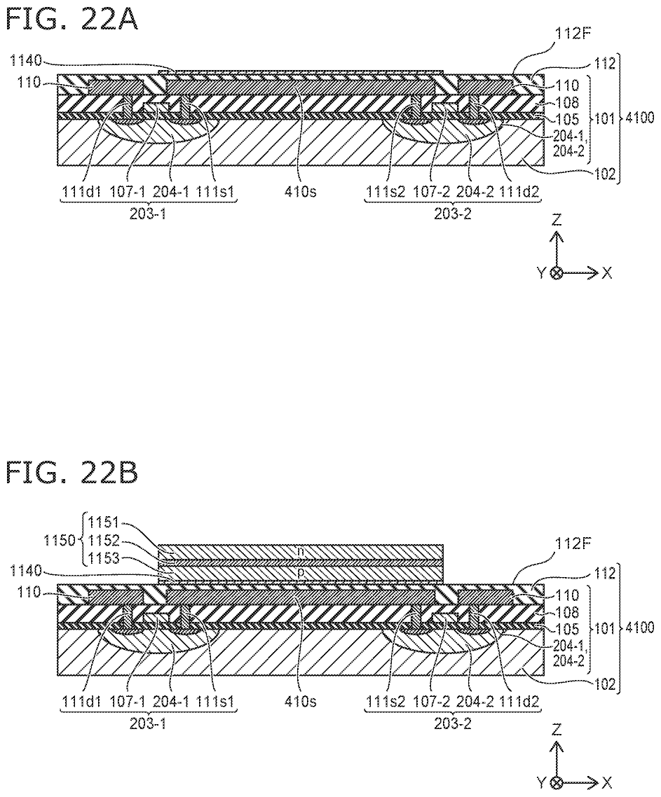

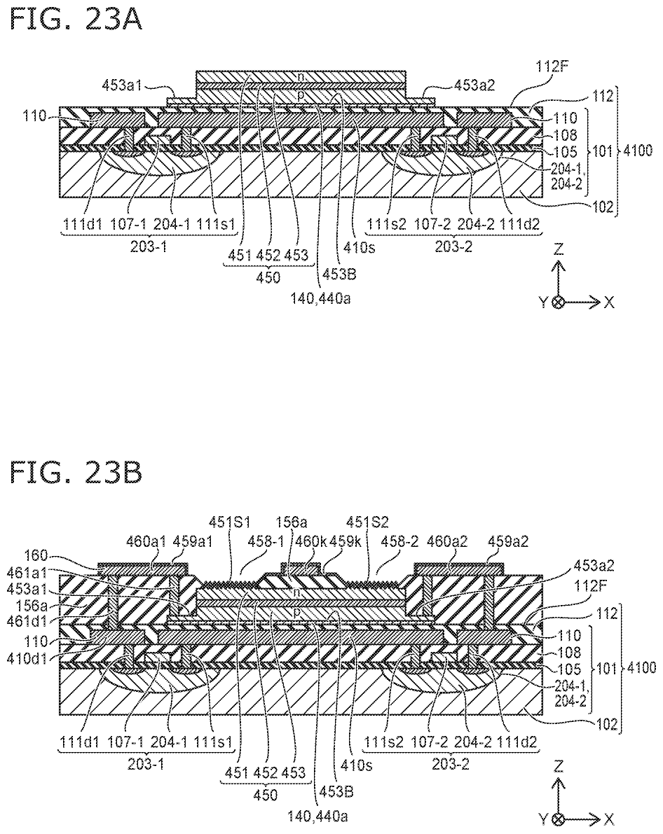

FIGS. 22A to 23B are schematic cross-sectional views illustrating the method for manufacturing the image display device of the embodiment.

A wafer 4100 is prepared as shown in FIG. 22A. The wafer 4100 includes the substrate 102, the circuit 101, and the first inter-layer insulating film 112. In the example, the circuit 101 includes the multiple element formation regions 204-1 and 204-2. The circuit 101 is covered with the first inter-layer insulating film 112. The wiring part 410s is described as being formed in a shape for shielding the downward-scattered light of the semiconductor layer 450 shown in FIG. 21. The graphene layer 1140 is formed on the planarized surface 112F in the prepared wafer 4100.

As shown in FIG. 22B, the semiconductor layer 1150 is formed on the graphene layer 1140. The semiconductor layer 1150 includes the p-type semiconductor layer 1153, the light-emitting layer 1152, and the n-type semiconductor layer 1151 formed in this order from the graphene layer 1140 side. To form the graphene layer 1140 and the semiconductor layer 1150, technology similar to that of the other embodiments described above is applicable.

As shown in FIG. 23A, the semiconductor layer 1150 shown in FIG. 22B is patterned by etching to form the semiconductor layer 450. In the formation process of the semiconductor layer 450, the connection parts 453a1 and 453a2 are formed, and then the portion other than the connection parts 453a1 and 453a2 is formed. In the formation process of the semiconductor layer 450, the semiconductor layer 450 is formed so that the outer perimeter of the wiring part 410s includes the outer perimeter of the semiconductor layer 450 when the semiconductor layer 450 is projected onto the wiring part 410s. That is, the semiconductor layer 450 is formed so that the outer perimeter of the semiconductor layer 450 is within the outer perimeter of the wiring part 410s when projected onto the XY plane. The graphene layer 1140 shown in FIG. 22B is over etched when forming the connection parts 453a1 and 453a2 to substantially match the outer perimeter of the semiconductor layer 450.

As shown in FIG. 23B, the second inter-layer insulating film 156a is formed to cover the planarized surface 112F, the graphene layer 140 including the graphene sheet 440a, and the semiconductor layer 450.

The via 461d1 is formed to extend through the second and first inter-layer insulating films 156a and 112 and reach the wiring part 410d1. The via 461d2 is formed to extend through the second and first inter-layer insulating films 156a and 112 and reach the wiring part 410d2. The via 461a1 is formed to extend through the second inter-layer insulating film 156a and reach the connection part 453a1. The via 461a2 is formed to extend through the second inter-layer insulating film 156a and reach the connection part 453a2.

The openings 458-1 and 458-2 are formed by removing portions of the second inter-layer insulating film 156a, and the light-emitting surfaces 451S1 and 451S2 are exposed from under the second inter-layer insulating film 156a respectively via the openings 458-1 and 458-2.

The second wiring layer 160 that includes the wiring parts 460a1, 460a2, and 460k is formed on the second inter-layer insulating film 156a, and the wiring part 460a1 is connected to the vias 461d1 and 461a1. The wiring part 460a2 is connected to the vias 461d2 and 461a2. The wiring part 460k is formed between the light-emitting surface 451S1 and the light-emitting surface 451S2.

The light-transmitting electrode 459a1 is formed over the wiring part 460a1. The light-transmitting electrode 459a2 is formed over the wiring part 460a2. The light-transmitting electrode 459k is formed over the wiring part 460k. The light-transmitting electrode 459k is formed over the light-emitting surfaces 451S1 and 451S2. The light-transmitting electrode 459k is formed between the wiring part 460k and the light-emitting surface 451S1 to electrically connect the wiring part 460k and the light-emitting surface 451S1. The light-transmitting electrode 459k is formed between the wiring part 460k and the light-emitting surface 451S2 to electrically connect the wiring part 460k and the light-emitting surface 451S2.

Thereafter, the subpixel group 420 of the image display device of the embodiment is formed by providing the color filter 180.

Although two light-emitting surfaces 451S1 and 451S2 are provided in one semiconductor layer 450 according to the example, the number of light-emitting surfaces is not limited to two; three or more light-emitting surfaces can be provided in one semiconductor layer 450. As an example, one column or two columns of subpixels may be realized using a single semiconductor layer 450. As described below, the recombination current that does not contribute to the light emission per light-emitting surface can be reduced thereby, and the effect of realizing a finer light-emitting element can be increased.

### Modification

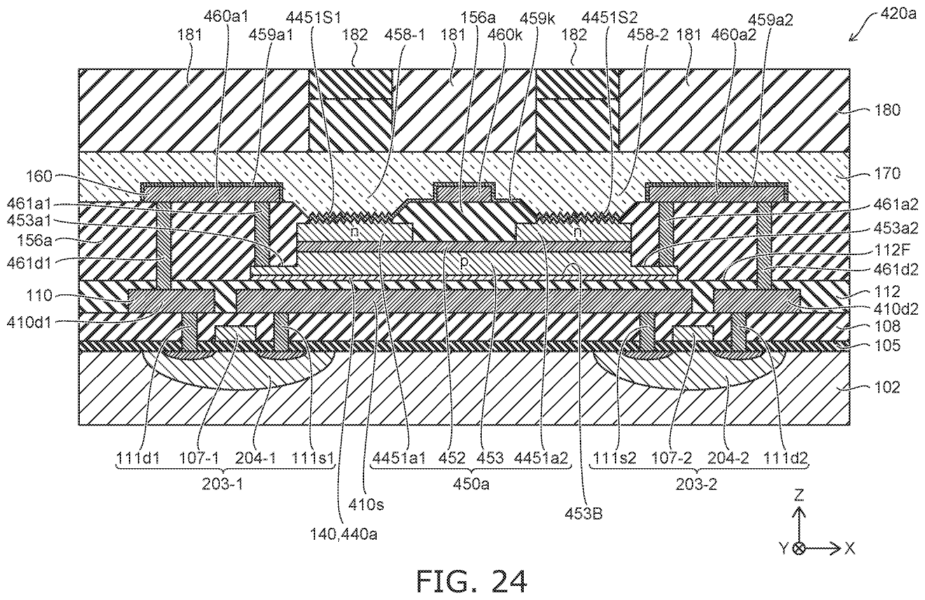

FIG. 24 is a schematic cross-sectional view illustrating a portion of an image display device according to the modification.

The modification differs from the fourth embodiment described above in that two n-type semiconductor layers 4451a1 and 4451a2 are located on the light-emitting layer 452. Otherwise, the modification is the same as the fourth embodiment; the same components are marked with the same reference numerals, and a detailed description is omitted as appropriate.

As shown in FIG. 24, the image display device of the modification includes a subpixel group 420a. The subpixel group 420a includes a semiconductor layer 450a. The semiconductor layer 450a includes the p-type semiconductor layer 453, the light-emitting layer 452, and the n-type semiconductor layers 4451a1 and 4451a2. The light-emitting layer 452 is stacked on the p-type semiconductor layer 453. The n-type semiconductor layers 4451a1 and 4451a2 each are stacked on the light-emitting layer 452.

The n-type semiconductor layers 4451a1 and 4451a2 are formed in an island configuration on the light-emitting layer 452 and are provided to be separated along the X-axis direction in the example. The second inter-layer insulating film 156a is located between the n-type semiconductor layer 4451a1 and the n-type semiconductor layer 4451a2, and the n-type semiconductor layers 4451a1 and 4451a2 are separated by the second inter-layer insulating film 156a.

In the example, the n-type semiconductor layers 4451a1 and 4451a2 have substantially the same shape when projected onto the XY plane, and the shape may be substantially a square, rectangle, other polygon, circle, etc.

The n-type semiconductor layer 4451a1 includes a light-emitting surface 4451S1. The n-type semiconductor layer 4451a2 includes a light-emitting surface 4451S2. The light-emitting surface 4451S1 is a surface of the n-type semiconductor layer 4451a1 exposed from under the second inter-layer insulating film 156a via the opening 458-1. The light-emitting surface 4451S2 is a surface of the n-type semiconductor layer 4451a2 exposed from under the second inter-layer insulating film 156a via the opening 458-2.

Similarly to the shapes of the light-emitting surfaces according to the fourth embodiment, the shapes of the light-emitting surfaces 4451S1 and 4451S2 when projected onto the XY plane are substantially the same shape and are substantially square, etc. The shapes of the light-emitting surfaces 4451S1 and 4451S2 are not limited to quadrangular such as that of the embodiment and may be circular, elliptical, polygonal such as hexagonal, etc. The shapes of the light-emitting surfaces 4451S1 and 4451S2 may be similar to or different from the shapes of the openings 458-1 and 458-2.

The light-transmitting electrode 459k is provided over the light-emitting surface 4451S1 and provided over the wiring part 460k. The light-transmitting electrode 459k is located between the light-emitting surface 4451S1 and the wiring part 460k and electrically connects the light-emitting surface 4451S1 and the wiring part 460k. The light-transmitting electrode 459k is provided over the light-emitting surface 4451S2, is located between the light-emitting surface 4451S2 and the wiring part 460k, and electrically connects the light-emitting surface 4451S2 and the wiring part 460k.

A manufacturing method of the modification will now be described.

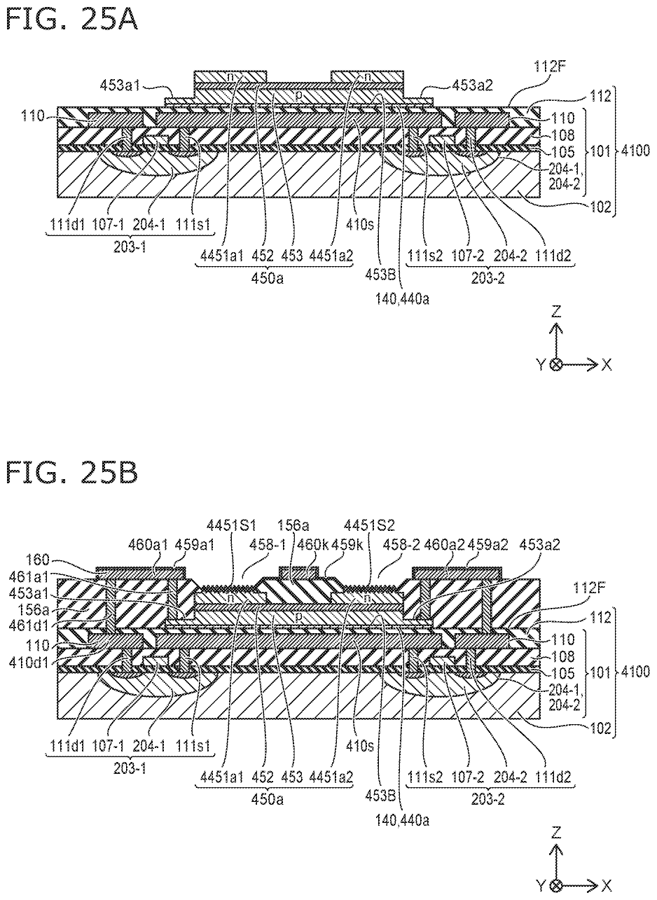

FIGS. 25A and 25B are schematic cross-sectional views illustrating the method for manufacturing the image display device of the modification.

In the description of the modification, the processes up to the process shown in FIG. 22B are the same processes as those of the fourth embodiment, and the process of FIG. 25A and subsequent processes are applied after the process shown in FIG. 22B.

As shown in FIG. 25A, the semiconductor layer 1150 shown in FIG. 22B is etched to form the connection parts 453a1 and 453a2, after which the light-emitting layer 452 and the p-type semiconductor layer 453 are formed from the remaining part. The two n-type semiconductor layers 4451a1 and 4451a2 are formed by further etching. The graphene layer 1140 shown in FIG. 22B is over etched when forming the semiconductor layer 450a to shape the graphene sheet 440a having an outer perimeter that substantially matches the outer perimeter of the semiconductor layer 450a.

The etching may be deeper when forming the n-type semiconductor layers 4451a1 and 4451a2. For example, the etching for forming the n-type semiconductor layers 4451a1 and 4451a2 may be performed to exceed a depth that reaches the light-emitting layer 452 and the p-type semiconductor layer 453. Thus, when the n-type semiconductor layers are formed by performing deep etching, it is desirable to etch outward of the outer perimeters of the light-emitting surfaces 4451S1 and 4451S2 shown in FIG. 24 by not less than 1 μm. The recombination current can be suppressed by separating the etching position outward further the outer perimeters of the light-emitting surfaces 4451S1 and 4451S2.

As shown in FIG. 25B, the second inter-layer insulating film 156a is formed to cover the planarized surface 112F, the graphene layer 140 including the graphene sheet 440a, and the semiconductor layer 450a. Subsequently, the openings 458-1 and 458-2, the vias 461d1, 461d2, 461a1, and 461a2, the second wiring layer 160, and the light-transmitting electrodes 459a1, 459a2, and 459k are formed similarly to those of the fourth embodiment.

The upper structure such as a color filter, etc., are formed similarly to those of the fourth embodiment.

Thus, the subpixel group 420a that includes the two light-emitting surfaces 4451S1 and 4451S2 is formed.

According to the modification as well, similarly to the fourth embodiment, the number of light-emitting surfaces is not limited to two; three or more light-emitting surfaces may be provided in one semiconductor layer 450a.

### Fifth Embodiment

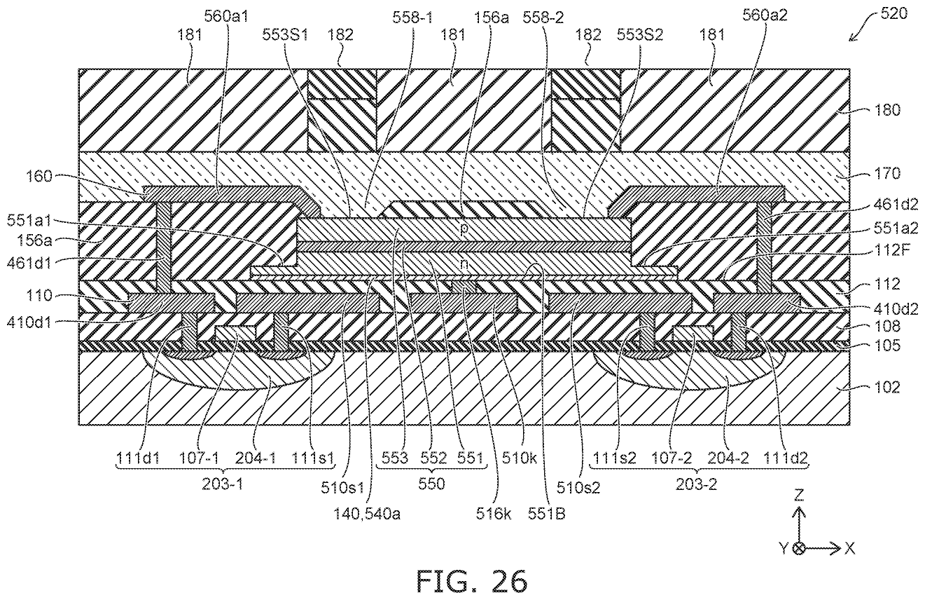

FIG. 26 is a schematic cross-sectional view illustrating a portion of an image display device according to the embodiment.

The embodiment differs from the fourth embodiment in that a semiconductor layer 550 and a wiring part 510k of the first wiring layer 110 are connected by a plug 516k. A graphene sheet 540a is located between the semiconductor layer 550 and the plug 516k at the connection between the semiconductor layer 550 and the plug 516k. Although the embodiment is the same as the fourth embodiment in that the semiconductor layer is caused to emit light by being driven by the p-channel transistors 203-1 and 203-2, the configuration of the semiconductor layer 550 is different from that of the fourth embodiment. The same components as the fourth embodiment are marked with the same reference numerals, and a detailed description is omitted as appropriate. Although an embodiment will now be described in which one end of a wiring part 560a1 is connected with a surface including a light-emitting surface 553S1 and one end of a wiring part 560a2 is connected with a surface including a light-emitting surface 553S2 in the second wiring layer 160, light-transmitting electrodes may be used to connect between the second wiring layer 160 and the light-emitting surfaces 553S1 and 553S2. Also, the light-emitting surfaces 553S1 and 553S2 may be roughened.

As shown in FIG. 26, the image display device of the embodiment includes a subpixel group 520. The subpixel group 520 includes the transistors (the multiple transistors) 203-1 and 203-2, the first wiring layer 110, the first inter-layer insulating film 112, the graphene layer 140, the semiconductor layer 550, the second inter-layer insulating film 156a, the second wiring layer 160, and the vias 461d1 and 461d2. In the subpixel group 520, the first wiring layer 110 includes wiring parts 510s1, 510s2, and 510k. The wiring part 510k is located between the wiring part 510s1 and the wiring part 510s2. For example, the wiring parts 510s1 and 510s2 are connected to the power supply line 3 of the circuit of FIG. 14. For example, the wiring part 510k is connected to the ground line 4 of the circuit of FIG. 14. The first wiring layer 110 also includes the wiring parts 410d1 and 410d2, and the wiring parts 410d1 and 410d2 have functions similar to the wiring parts 410d1 and 410d2 according to the fourth embodiment.

The wiring parts 510s1, 510s2, and 510k are located below the semiconductor layer 550 and are provided to shield the downward-scattered light radiated from the semiconductor layer 550. The spacing between the wiring part 510s1 and the wiring part 510k is set to be a narrow spacing that is sufficient to ensure the potential difference that may occur between the wiring part 510s1 and the wiring part 510k. The spacing between the wiring part 510s2 and the wiring part 510k also is set to be a narrow spacing that is sufficient to ensure the potential difference that may occur between the wiring part 510s2 and the wiring part 510k. Also, it is favorable to set the envelope of the outer perimeters of the wiring parts 510s1, 510k, and 510s2 when projected onto the XY plane to include the outer perimeter of the semiconductor layer 550 when the semiconductor layer 550 is projected into a region surrounding the envelope when projected onto the XY plane. That is, it is favorable to set the outer perimeter of the semiconductor layer 550 to be within the outer perimeter of the envelopes of the wiring parts 510s1, 510k, and 510s2 when projected onto the XY plane.

The graphene layer 140 includes the graphene sheet (the third part) 540a. The graphene layer 140 includes multiple graphene sheets 540a, and the graphene sheet 540a is provided for each semiconductor layer 550.

The plug 516k is located between the wiring part 510k (the first wiring part) and the graphene sheet 540a. The plug 516k electrically connects the wiring part 510k and the graphene sheet 540a. Because the graphene sheet 540a is sufficiently thin, the conductivities of the graphene sheet 540a and the graphene layer 140 in the thickness direction are values that can allow the flow of enough current for the light-emitting surfaces 553S1 and 553S2 to emit light of the desired brightness. The semiconductor layer 550 is electrically connected to the wiring part 510k with a low resistance via the plug 516k and the graphene sheet 540a.

The semiconductor layer 550 includes an n-type semiconductor layer 551, a light-emitting layer 552, and a p-type semiconductor layer 553. The semiconductor layer 550 includes the n-type semiconductor layer 551, the light-emitting layer 552, and the p-type semiconductor layer 553 stacked in this order from the planarized surface 112F toward the light-emitting surfaces 553S1 and 553S2. A bottom surface 551B is a surface of the n-type semiconductor layer 551, and the n-type semiconductor layer 551 is electrically connected to the graphene sheet 540a at the bottom surface 551B. The bottom surface 551B is a surface at the side opposite to the surface including the light-emitting surfaces 553S1 and 553S2.

Although the n-type semiconductor layer 551 includes connection parts 551a1 and 551a2 having staircase shapes in the example, the semiconductor layer 550 may be a single prism or circular columnar shape that does not include the connection parts 551a1 and 551a2.

The second inter-layer insulating film 156a is provided to cover the planarized surface 112F, the graphene layer 140 including the graphene sheet 540a, and the semiconductor layer 550. An opening 558-1 is formed by removing a portion of the second inter-layer insulating film 156a. The light-emitting surface 553S1 is exposed from under the second inter-layer insulating film 156a via the opening 558-1. An opening 558-2 is formed by removing a portion of the second inter-layer insulating film 156a. The light-emitting surface 553S2 is exposed from under the second inter-layer insulating film 156a via the opening 558-2.

The second wiring layer 160 is located on the second inter-layer insulating film 156a. The second wiring layer 160 includes the wiring parts 560a1 and 560a2. One end of the wiring part 560a1 is connected to a surface including the light-emitting surface 553S1. The via 461d1 is located between the wiring part 560a1 and the wiring part 410d1 and electrically connects the wiring part 560a1 and the wiring part 410d1. Accordingly, the light-emitting surface 553S1 of the p-type semiconductor layer 553 is electrically connected to the drain electrode of the transistor 203-1 via the wiring part 560a1, the via 461d1, the wiring part 410d1, and the via 111d1. One end of the wiring part 560a2 is connected to a surface including the light-emitting surface 553S2. The via 461d2 is located between the wiring part 560a2 and the wiring part 410d2 and electrically connects the wiring part 560a2 and the wiring part 410d2. The light-emitting surface 553S2 of the p-type semiconductor layer 553 is electrically connected to the drain electrode of the transistor 203-2 via the wiring part 560a2, the via 461d2, the wiring part 410d2, and the via 111d2.

The embodiment is advantageous in that the n-type semiconductor layer 551 can be electrically connected with a low resistance by being connected to the wiring part 510k via the graphene sheet 540a and the plug 516k.

By applying the manufacturing method of the third embodiment described using FIGS. 18A to 20A to the modification, the plug 516k can be formed, and the plug 516k and the graphene sheet 140a can be electrically connected.

### Modification

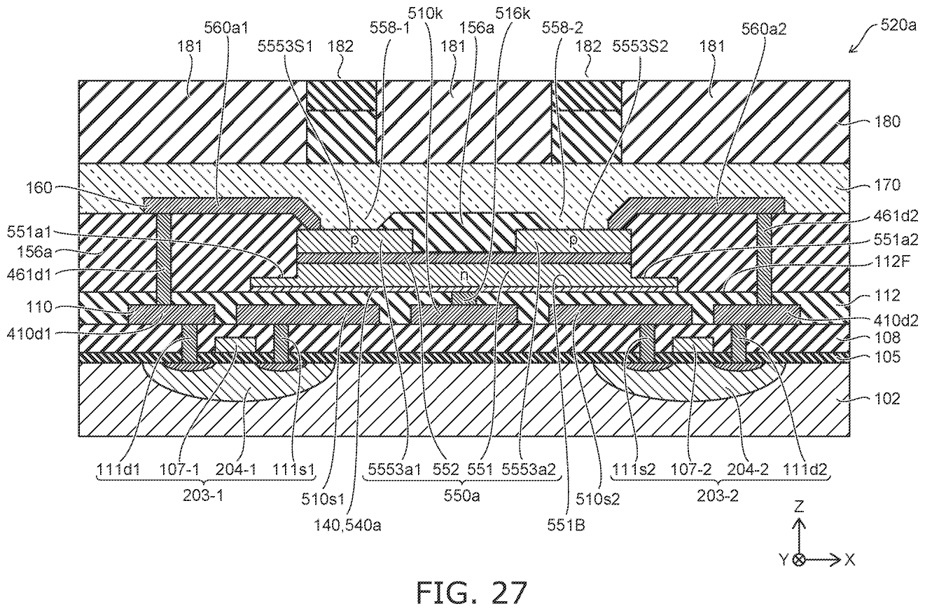

FIG. 27 is a schematic cross-sectional view illustrating a portion of an image display device according to the modification.

The modification differs from the fifth embodiment and is similarly to the modification of the fourth embodiment in that p-type semiconductor layers 5553a1 and 5553a2 that respectively provide light-emitting surfaces 5553S1 and 5553S2 are separated in an island configuration. Otherwise, the modification is the same as the fifth embodiment.

As shown in FIG. 27, the image display device of the modification includes a subpixel group 520a. The subpixel group 520a includes a semiconductor layer 550a, the plug 516k, and the first wiring layer 110 including the wiring parts 510s1, 510s2, and 510k.

The semiconductor layer 550a includes the n-type semiconductor layer 551, the light-emitting layer 552, and the p-type semiconductor layers 5553a1 and 5553a2. The light-emitting layer 552 is stacked on the n-type semiconductor layer 551. The p-type semiconductor layers 5553a1 and 5553a2 each are stacked on the light-emitting layer 552.

The p-type semiconductor layers 5553a1 and 5553a2 are formed in an island configuration on the light-emitting layer 552, and are provided to be separated along the X-axis direction in the example. The second inter-layer insulating film 156a is located between the p-type semiconductor layer 5553a1 and the p-type semiconductor layer 5553a2, and the p-type semiconductor layers 5553a1 and 5553a2 are separated by the second inter-layer insulating film 156a.

In the example, the p-type semiconductor layers 5553a1 and 5553a2 have substantially the same shape when projected onto the XY plane, and the shape may be substantially a square, rectangle, other polygon, circle, etc.

The p-type semiconductor layer 5553a1 includes the light-emitting surface 5553S1. The p-type semiconductor layer 5553a2 includes the light-emitting surface 5553S2. The light-emitting surface 5553S1 is a surface of the p-type semiconductor layer 5553a1 exposed from under the second inter-layer insulating film 156a via the opening 558-1. The light-emitting surface 5553S2 is a surface of the p-type semiconductor layer 5553a2 exposed from under the second inter-layer insulating film 156a via the opening 558-2.

Similarly to the shapes of the light-emitting surface according to the modification of the fourth embodiment, the shapes of the light-emitting surfaces 5553S1 and 5553S2 when projected onto the XY plane have substantially the same shape and are substantially square, etc. The shapes of the light-emitting surfaces 5553S1 and 5553S2 are not limited to quadrangular as in the embodiment and may be circular, elliptical, polygonal such as hexagonal, etc. The shapes of the light-emitting surfaces 5553S1 and 5553S2 may be similar to or different from the shapes of the openings 558-1 and 558-2.

The other components are similar to those of the fifth embodiment. The fifth embodiment can be similarly applied to the formation process of the plug 516k and the connection process between the plug 516k and the graphene sheet 540a. The processes described in the modification of the fourth embodiment can be easily applied to the formation process of the semiconductor layer 550a by modifying the polarities of the semiconductor layers.

Effects of the image display devices of the fourth and fifth embodiments and their modifications will now be described.

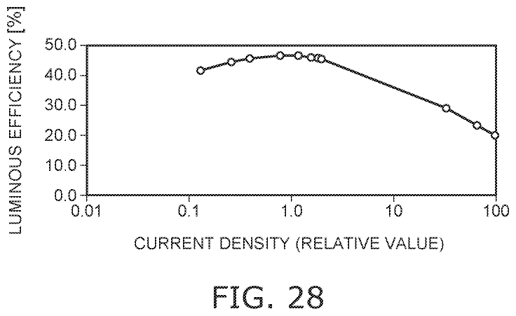

FIG. 28 is a graph illustrating a characteristic of a pixel LED element.

The vertical axis of FIG. 28 is the luminous efficiency (%) of the pixel LED element. The horizontal axis is the current density of the current flowing in the pixel LED element shown as a relative value.

As shown in FIG. 28, the luminous efficiency of the pixel LED element is substantially constant or monotonously increases in the region in which the relative value of the current density is less than 1.0. The luminous efficiency monotonously decreases in the region in which the relative value of the current density is greater than 1.0. That is, an appropriate current density at which the luminous efficiency has a maximum exists in the pixel LED element.

It may be expected that a highly efficient image display device is realized by suppressing the current density so that a sufficient luminance is obtained from the light-emitting element. However, it is shown by FIG. 28 that there is a tendency for the current density to decrease and for the luminous efficiency to decrease for a low current density.

As described in the first to third embodiments, the light-emitting element is formed by individually singulating by etching or the like of all of the layers of the semiconductor layer 1150 that includes the light-emitting layer. At this time, the bonding surface between the light-emitting layer and the p-type semiconductor layer is exposed at the end portion of the light-emitting element. Similarly, the bonding surface between the light-emitting layer and the n-type semiconductor layer is exposed at the end portion.

When such end portions exist, electrons and holes recombine at the end portions. On the other hand, such recombination does not contribute to the light emission. The recombination at the end portions occurs substantially regardless of the current caused to flow in the light-emitting element. It is considered that the recombination occurs according to the lengths of the bonding surfaces that contribute to the light emission at the end portions.

When two light-emitting elements that have cubic shapes of the same dimension emit light, end portions are formed at four side surfaces for each light-emitting element; therefore, the two light-emitting elements have a total of eight end portions, and recombination may occur at eight end portions.

In contrast, according to the fourth and fifth embodiments and their modifications, the semiconductor layers 450, 450a, 550, and 550a include four side surfaces, and there are four end portions of the two light-emitting surfaces. However, the region between the two openings substantially does not contribute to the light emission because few electrons and holes are injected; therefore, the end portions that contribute to the light emission can be considered to be six. Thus, according to the embodiment, by substantially reducing the number of end portions of the semiconductor layer, the recombination that does not contribute to the light emission is reduced. By reducing the recombination that does not contribute to the light emission, the drive current per light-emitting surface is reduced.

When reducing the distance between the subpixels for higher-definition of the image display device or the like, when the current density is relatively high, etc., the distance between the two light-emitting surfaces becomes substantially short in the subpixel groups 420 and 520 of the fourth and fifth embodiments. In such a case, when the n-type semiconductor layer 451 or the p-type semiconductor layer 553 that provides the light-emitting surface is shared, there is a risk that a portion of the electrons or holes injected into the light-emitting surface being driven may shunt, and the light-emitting surface that is not being driven may have a micro light emission. In contrast, in the subpixel groups 420a and 520a of the modifications of these embodiments, the semiconductor layer that provides the light-emitting surfaces is divided for each light-emitting surface; therefore, substantially no current flows in the light-emitting surface at the side not being driven, and the micro light emission of the light-emitting surface at the side not being driven can be reduced.

According to the fourth and fifth embodiments and their modifications, the semiconductor layers that include the light-emitting layers are formed by crystal growth on the graphene layer 1140 and are favorable from the perspective of reducing the manufacturing cost compared to when semiconductor layers are formed and individually transferred. Similarly to the first to third embodiments, the p-type semiconductor layer, the light-emitting layer, and the n-type semiconductor layer may be stacked in this order from the graphene sheet 140a side as described above instead of the stacking order of the n-type semiconductor layer and the p-type semiconductor layer.

According to the fifth embodiment and its modification, the semiconductor layer can be connected to the circuit 101 of the lower layer by using a plug, and a high density arrangement of the circuit elements is possible. Also, a yield increase is expected because the draw-out structure of the wiring parts for connecting with the external wiring is simplified.

Specific examples of the subpixels and subpixel groups of the image display devices of the embodiments are described above. Each specific example is an example, and other configuration examples are possible by appropriately combining the configurations and procedures of processes of these embodiments.

### Sixth Embodiment

The image display devices described above can be used as an image display module having the appropriate number of pixels in, for example, a computer display, a television, a portable terminal such as a smartphone, car navigation, etc.

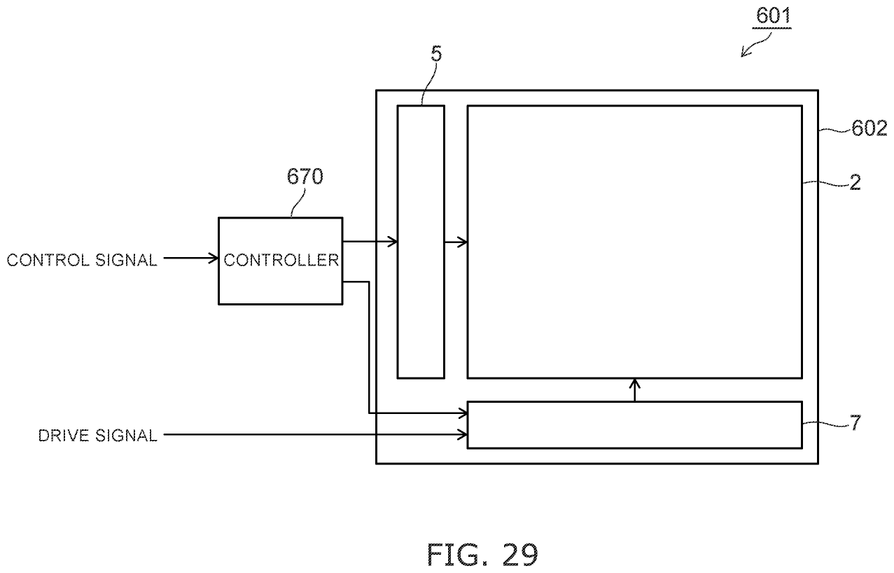

FIG. 29 is a block diagram illustrating an image display device according to the embodiment.

FIG. 29 shows the major parts of the configuration of a computer display.

As shown in FIG. 29, the image display device 601 includes an image display module 602. The image display module 602 is, for example, an image display device that includes the configuration according to the first embodiment described above. The image display module 602 includes the display region 2 in which the multiple subpixels including the subpixels 20 are arranged, the row selection circuit 5, and the signal voltage output circuit 7.

The image display device 601 further includes a controller 670. The controller 670 receives input of control signals to be separated and generated by not-illustrated interface circuitry, and controls the driving and the drive sequence of the subpixels in the row selection circuit 5 and the signal voltage output circuit 7.

### Modification

The image display device described above can be used as an image display module having the appropriate number of pixels in, for example, a computer display, a television, a portable terminal such as a smartphone, car navigation, etc.

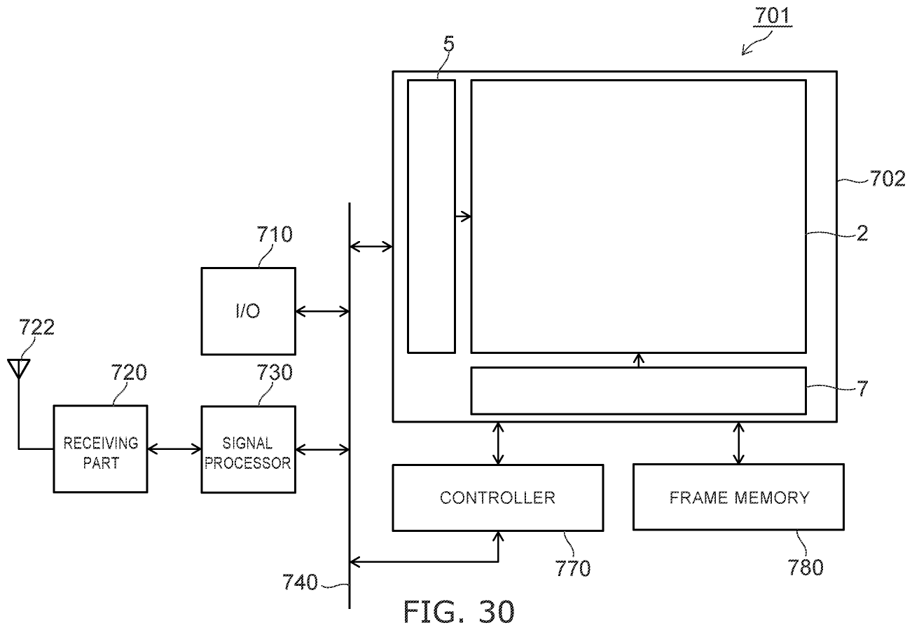

FIG. 30 is a block diagram illustrating an image display device according to a modification of the embodiment.

FIG. 30 shows the configuration of a high-definition thin television.

As shown in FIG. 30, the image display device 701 includes an image display module 702. The image display module 702 is, for example, the image display device 1 that includes the configuration according to the first embodiment described above. The image display device 701 includes a controller 770 and a frame memory 780. The controller 770 controls the drive sequence of the subpixels of the display region 2 based on a control signal supplied by a bus 740. The frame memory 780 stores one frame of display data and is used for smooth processing such as video image reproduction, etc.

The image display device 701 includes an I/O circuit 710. The I/O circuit 710 is labeled as simply “I/O” in FIG. 30. The I/O circuit 710 provides interface circuitry for connecting with an external terminal, a device, etc. The I/O circuit 710 includes, for example, an audio interface, a USB interface that connects an external hard disk device, etc.

The image display device 701 includes a receiving part 720 and a signal processor 730. An antenna 722 is connected to the receiving part 720, and the necessary signal is separated and generated from the radio wave received by the antenna 722. The signal processor 730 includes a DSP (Digital Signal Processor), a CPU (Central Processing Unit), etc., and the signal that is separated and generated by the receiving part 720 is separated and generated into image data, voice data, etc., by the signal processor 730.

Other image display devices also can be made by using the receiving part 720 and the signal processor 730 as a high-frequency communication module for the transmission and reception of a mobile telephone, for WiFi, a GPS receiver, etc. For example, the image display device that includes an image display module having the appropriate screen size and resolution can be used as a personal digital assistant such as a smartphone, a car navigation system, etc.

The image display module according to the embodiment is not limited to the configuration of the image display device according to the first embodiment; modifications of the first embodiment, the second to fifth embodiments, or modifications of the second to fifth embodiments may be used. Also, it goes without saying that the configurations of the image display module according to the embodiment and modifications include many subpixels as shown in FIG. 12.

According to the embodiments described above, a method for manufacturing an image display device and an image display device can be realized in which a transfer process of a light-emitting element is shortened, and the yield is increased.

Although several embodiments of the invention are described hereinabove, these embodiments have been presented by way of example only, and are not intended to limit the scope of the inventions. These novel embodiments may be embodied in a variety of other forms, and various omissions, substitutions, and changes may be made without departing from the spirit of the inventions. Such embodiments and their modifications are within the scope and spirit of the inventions, and are within the scope of the inventions described in the claims and their equivalents. Also, the embodiments described above can be implemented in combination with each other.

What is claimed is:

1. A method for manufacturing an image display device, the method comprising:
preparing a substrate, the substrate comprising a circuit and a first insulating film covering the circuit;
forming a graphene-including layer on the first insulating film;
forming a semiconductor layer on the graphene-including layer, the semiconductor layer comprising a light-emitting layer;
forming a light-emitting element by etching the semiconductor layer, the light-emitting element including a bottom surface on the graphene-including layer, and a light-emitting surface at a side opposite to the bottom surface;
forming a second insulating film covering the graphene-including layer, the light-emitting element, and the first insulating film;
forming a first via extending through the first and second insulating films; and
forming a wiring layer on the second insulating film, wherein:
the first via is located between the wiring layer and the circuit and electrically connects the wiring layer and the circuit,
the light-emitting element is electrically connected to the circuit via the wiring layer.

2. The method according to claim 1, wherein
in the forming of the semiconductor layer, the semiconductor layer is formed by sputtering.

3. The method according to claim 1, further comprising:
forming a second via extending through the second insulating film, wherein:
the light-emitting element comprises a connection part formed on the graphene-including layer,
the second via is located between the wiring layer and the connection part, and
the light-emitting element is electrically connected to the circuit via the connection part, the second via, the wiring layer, and the first via.

4. The method according to claim 1, wherein:
the substrate comprises a plug electrically connected to the circuit, and
in the forming of the graphene-including layer, the graphene-including layer is formed on the plug and the first insulating film.

5. The method according to claim 1, further comprising:
exposing the light-emitting surface.

6. The method according to claim 5, further comprising:
forming a light-transmitting electrode on the exposed light-emitting surface.

7. The method according to claim 1, wherein:
the semiconductor layer comprises a gallium nitride compound semiconductor.

8. The method according to claim 1, further comprising:
forming a wavelength conversion member on the light-emitting element.

9. An image display device comprising:
a circuit element;
a first wiring layer electrically connected to the circuit element;
a first insulating film covering the circuit element and the first wiring layer;
a first part located on the first insulating film, the first part comprising graphene;
a light-emitting element including a bottom surface on the first part, and a light-emitting surface at a side opposite to the bottom surface;
a second insulating film covering the first insulating film and a side surface of the light-emitting element;
a second wiring layer located on the second insulating film; and
a first via extends through the first and second insulating films, the first via being located between the first wiring layer and the second wiring layer and electrically connecting the first wiring layer and the second wiring layer, wherein:
the light-emitting element is electrically connected to the circuit element via at least one of the first wiring layer or the second wiring layer.

10. The image according to claim 9, further comprising:
a second via extending through the second insulating film,
wherein:
the light-emitting element comprises a connection part formed on the graphene-including layer;
the second via is located between the connection part the second wiring layer, and electrically connecting the connection part and the second wiring layer; and
the light-emitting element is electrically connected to the circuit element via the connection part, the second via, the second wiring layer, the first via, and the first wiring layer.

11. The image according to claim 9, wherein:
the first wiring layer comprises:
a first wiring part to which the first via is connected, and
a second wiring part separated from the first wiring part,
the image display device further comprises a plug located between the first part and the first wiring part, and
the light-emitting element is electrically connected to the first wiring part via the first part and the plug.

12. The image according to claim 9, wherein:
the first wiring layer comprises a second part, the second part being light-shielding,
the light-emitting element is located on the second part,
in a plan view, an outer perimeter of the light-emitting element is within an outer perimeter of the second part when the light-emitting element is projected onto the second part.

13. The image according to claim 9, wherein:
the second insulating film includes an opening in which the light-emitting surface is exposed, and
the image display device further comprises a light-transmitting electrode located on the light-emitting surface.

14. The image according to claim 9, wherein:
the light-emitting element includes:
a first semiconductor layer,
a light-emitting layer located on the first semiconductor layer, and
a second semiconductor layer located on the light-emitting layer,
the first semiconductor layer, the light-emitting layer, and the second semiconductor layer are stacked in this order from the bottom surface toward the light-emitting surface,
the first semiconductor layer is of an n-type, and
the second semiconductor layer is of a p-type.

15. The image according to claim 9, wherein:
the light-emitting element comprises a gallium nitride compound semiconductor.

16. The image according to claim 9, further comprising:
a wavelength conversion member on the light-emitting element.

17. An image display device comprising:
a plurality of transistors;
a first wiring layer electrically connected to the plurality of transistors;
a first insulating film covering the plurality of transistors and the first wiring layer;
a third part located on the first insulating film, the third part comprising graphene;
a semiconductor layer including a first surface on the third part, and a plurality of light-emitting surfaces at a second surface at a side opposite to the first surface;
a second insulating film covering the first insulating film and a side surface of the semiconductor layer;
a second wiring layer located on the second insulating film; and
a via extending through the first and second insulating films, the via being located between the first wiring layer and the second wiring layer and electrically connecting the first wiring layer and the second wiring layer, wherein:
the semiconductor layer is electrically connected to the plurality of transistors via the first and second wiring layers.

18. The image according to claim 17, wherein:
the first wiring layer comprises a first wiring part insulated from the via,
the image display device further comprises a plug located between the third part and the first wiring part, and
the semiconductor layer is electrically connected to the first wiring part via the third part and the plug.

19. The image according to claim 17, wherein:
the semiconductor layer includes:
a first semiconductor layer,
a light-emitting layer located on the first semiconductor layer, and
a second semiconductor layer located on the light-emitting layer,
the second semiconductor layer is of a different conductivity type from the first semiconductor layer,
the first semiconductor layer, the light-emitting layer, and the second semiconductor layer are stacked in this order from the third part toward the plurality of light-emitting surfaces, and
the second semiconductor layer is separated into a plurality by the second insulating film.

20. An image display device comprising:
a plurality of circuit elements;
a first wiring layer electrically connected to the plurality of circuit elements;
a first insulating film covering the plurality of circuit elements and the first wiring layer;
a plurality of first parts located on the first insulating film, the plurality of first parts comprising graphene;
a plurality of light-emitting elements including bottom surfaces on the plurality of first parts, and light-emitting surfaces at sides opposite to the bottom surfaces;
a second insulating film covering the first insulating film and side surfaces of the plurality of light-emitting elements;
a second wiring layer located on the second insulating film; and
a first via extending through the first and second insulating films, the first via being located between the first wiring layer and the second wiring layer and electrically connecting the first wiring layer and the second wiring layer, wherein:
the plurality of light-emitting elements are electrically connected respectively to the plurality of circuit elements via at least one of the first wiring layer or the second wiring layer.
